(19) United States
(12) Patent Application Publication
(10) Pub. No.: US 2018/0366632 A1
(43) Pub. Date: Dec. 20, 2018

(54) THERMOELECTRIC CONVERSION LAYER, THERMOELECTRIC CONVERSION ELEMENT, AND COMPOSITION FOR FORMING THERMOELECTRIC CONVERSION LAYER

(71) Applicant: FUJIFILM Corporation, Tokyo (JP)

(72) Inventors: Yoshinori KANAZAWA, Ashigara-kami-gun (JP); Yuzo NAGATA, Ashigara-kami-gun (JP); Hiroki SUGIURA, Ashigara-kami-gun (JP); Naoyuki HAYASHI, Ashigara-kami-gun (JP); Kimiatsu NOMURA, Ashigara-kami-gun (JP)

(73) Assignee: FUJIFILM Corporation, Tokyo (JP)

(21) Appl. No.: 16/004,749

(22) Filed: Jun. 11, 2018

Related U.S. Application Data
(63) Continuation of application No. PCT/JP2016/087418, filed on Dec. 15, 2016.

(30) Foreign Application Priority Data
Dec. 18, 2015 (JP) 2015-247649

(51) Int. Cl. H01L 35/24

(52) U.S. Cl. CPC H01L 35/24; H01L 51/0049

(57) ABSTRACT

An object of the present invention is to provide a thermoelectric conversion layer, which has a high power factor and a low thermal conductivity and exhibits the characteristics of an n-type excellently maintaining performance stability even being exposed to a high temperature for a long period of time, a thermoelectric conversion element having the thermoelectric conversion layer as an n-type thermoelectric conversion layer, and a composition for forming a thermoelectric conversion layer used for forming the thermoelectric conversion layer.

The thermoelectric conversion layer of the present invention contains a carbon nanotube-containing n-type thermoelectric conversion material and a hydrogen bonding resin.

### CROSS-REFERENCE TO RELATED APPLICATIONS

This application is a Continuation of PCT International Application No. PCT/JP2016/087418 filed on Dec. 15, 2016, which claims priority under 35 U.S.C. § 119(a) to Japanese Patent Application No. 2015-247649 filed on Dec. 18, 2015. The above application is hereby expressly incorporated by reference, in its entirety, into the present application.

### BACKGROUND OF THE INVENTION

### 1. Field of the Invention

The present invention relates to a thermoelectric conversion layer, a thermoelectric conversion element, and a composition for forming a thermoelectric conversion layer.

### 2. Description of the Related Art

Thermoelectric conversion materials that enable the interconversion of thermal energy and electric energy are used in power generating elements generating electric power from heat or thermoelectric conversion elements such as a Peltier element. Thermoelectric conversion elements can convert thermal energy directly into electric power, do not require a moving portion, and are used in, for example, wrist watches operating by body temperature, power supplies for backwoods, and aerospace power supplies.

The thermoelectric conversion materials are roughly classified into two types including a p-type thermoelectric conversion material and an n-type thermoelectric conversion material. Generally, as the n-type thermoelectric conversion material, an inorganic material such as nickel is known. Unfortunately, the inorganic material is expensive, contains toxic substances, and needs to undergo a complicated process for being made into a thermoelectric conversion element.

Therefore, in recent years, techniques using carbon materials represented by carbon nanotubes (hereinafter, referred to as “CNT” as well) have been suggested. For example, Scientific Reports 2013, 3, 3344-1-7 discloses an aspect in which an n-type thermoelectric conversion material is provided by adding a dopant for a change to an n-type to carbon nanotubes.

### SUMMARY OF THE INVENTION

Meanwhile, in recent years, in order to improve the performance of instruments using thermoelectric conversion elements, further improvement of the thermoelectric conversion performance of the thermoelectric conversion elements has been required.

In line with this trend, the inventors of the present invention prepared an n-type thermoelectric conversion material by adding triphenylphosphine as a dopant to CNT based on the description of Scientific Reports 2013, 3, 3344-1-7 and prepared a thermoelectric conversion layer by using the obtained n-type thermoelectric conversion material. As a result, it was revealed that the thermoelectric conversion layer does not always satisfy the thermoelectric conversion performance (particularly, a power factor (hereinafter, referred to as “PF” as well) and a thermal conductivity) that has been recently required. Furthermore, it was revealed that, in a case where the thermoelectric conversion layer is exposed to a high-temperature environment for a long period of time, the thermoelectric conversion performance such as a Seebeck coefficient deteriorates, and the performance stability becomes insufficient in some cases.

The present invention has been made in consideration of the circumstances described above, and an object thereof is to provide a thermoelectric conversion layer, which has a high power factor and a low thermal conductivity and exhibits the characteristics of an n-type maintaining excellent performance stability even being exposed to a high temperature for a long period of time, a thermoelectric conversion element having the thermoelectric conversion layer as an n-type thermoelectric conversion layer, and a composition for forming a thermoelectric conversion layer used for forming the thermoelectric conversion layer.

In order to achieve the aforementioned object, the inventors of the present invention performed an intensive examination. As a result, the inventors have found that the aforementioned object can be achieved using a hydrogen bonding resin.

That is, the inventors of the present invention have found that the aforementioned object can be achieved by the following constitutions.

(1) A thermoelectric conversion layer comprising a carbon nanotube-containing n-type thermoelectric conversion material and a hydrogen bonding resin.

(2) The thermoelectric conversion layer described in (1), in which the carbon nanotube-containing n-type thermoelectric conversion material contains carbon nanotubes and at least one kind of dopant for a change to an n-type.

(3) The thermoelectric conversion layer described in (2), in which in the carbon nanotube-containing n-type thermoelectric conversion material, a content of the dopant for a change to an n-type is 7% to 200% by mass with respect to a content of the carbon nanotubes.

(4) The thermoelectric conversion layer described in (2) or (3), in which a content of the hydrogen bonding resin is 2% to 80% by mass with respect to the content of the carbon nanotubes.

(5) The thermoelectric conversion layer described in any one of (2) to (4), in which the dopant for a change to an n-type is at least one kind of compound selected from the group consisting of a polyoxyalkylene-based compound, an amine-based compound, and a phosphine-based compound.

(6) The thermoelectric conversion layer described in any one of (1) to (5), in which the hydrogen bonding resin is a polysaccharide.

(7) The thermoelectric conversion layer described in (6), in which the hydrogen bonding resin has a carboxyl group or a salt thereof.

(8) The thermoelectric conversion layer described in (7), in which the hydrogen bonding resin is a cellulose derivative.

(9) The thermoelectric conversion layer described in any one of (2) to (8), in which the dopant for a change to an n-type is a polyoxyalkylene-based compound.

(10) A thermoelectric conversion element comprising the thermoelectric conversion layer described in any one of (1) to (9) as an n-type thermoelectric conversion layer.

(11) The thermoelectric conversion element described in (10), further comprising a p-type thermoelectric conversion layer electrically connected to the n-type thermoelectric conversion layer, in which the p-type thermoelectric conversion layer contains carbon nanotubes.

(12) A composition for forming a thermoelectric conversion layer, comprising a carbon nanotube-containing n-type thermoelectric conversion material and a hydrogen bonding resin.

(13) The composition for forming a thermoelectric conversion layer described in (12), in which the carbon nanotube-containing n-type thermoelectric conversion material contains carbon nanotubes and at least one kind of dopant for a change to an n-type.

(14) The composition for forming a thermoelectric conversion layer described in (13), in which in the carbon nanotube-containing n-type thermoelectric conversion material, a content of the dopant for a change to an n-type is 7% to 200% by mass with respect to a content of the carbon nanotubes.

(15) The composition for forming a thermoelectric conversion layer described in (13) or (14) in which a content of the hydrogen bonding resin is 2% to 80% by mass with respect to the content of the carbon nanotubes.

(16) The composition for forming a thermoelectric conversion layer described in any one of (13) to (15), in which the dopant for a change to an n-type is at least one kind of compound selected from the group consisting of a polyoxyalkylene-based compound, an amine-based compound, and a phosphine-based compound.

(17) The composition for forming a thermoelectric conversion layer described in any one of (12) to (16), in which the hydrogen bonding resin is a polysaccharide.

(18) The composition for forming a thermoelectric conversion layer described in (17), in which the hydrogen bonding resin has a carboxyl group or a salt thereof.

(19) The composition for forming a thermoelectric conversion layer described in (18), in which the hydrogen bonding resin is a cellulose derivative.

(20) The composition for forming a thermoelectric conversion layer described in any one of (13) to (19), in which the dopant for a change to an n-type is a polyoxyalkylene-based compound.

According to the present invention, it is possible to provide a thermoelectric conversion layer, which has a high power factor and a low thermal conductivity and exhibits the characteristics of an n-type maintaining excellent performance stability even being exposed to a high temperature for a long period of time, a thermoelectric conversion element having the thermoelectric conversion layer as an n-type thermoelectric conversion layer, and a composition for forming a thermoelectric conversion layer used for forming the thermoelectric conversion layer.

### BRIEF DESCRIPTION OF THE DRAWINGS

FIG. 1 is a cross-sectional view of a first embodiment of a thermoelectric conversion element of the present invention.

FIG. 2 is a cross-sectional view of a second embodiment of the thermoelectric conversion element of the present invention.

FIG. 3A is a conceptual view (top view) of a third embodiment of the thermoelectric conversion element of the present invention.

FIG. 3B is a conceptual view (front view) of the third embodiment of the thermoelectric conversion element of the present invention.

FIG. 3C is a conceptual view (bottom view) of the third embodiment of the thermoelectric conversion element of the present invention.

FIG. 4 is a conceptual view of a fourth embodiment of the thermoelectric conversion element of the present invention.

FIG. 5 is a conceptual view of a fifth embodiment of the thermoelectric conversion element of the present invention.

### DESCRIPTION OF THE PREFERRED EMBODIMENTS

Hereinafter, the thermoelectric conversion layer, the thermoelectric conversion element, and the composition for forming a thermoelectric conversion layer of the present invention will be described.

In the present specification, “(meth)acrylate” represents either or both of acrylate and methacrylate, and includes a mixture of these.

In the present specification, a range of numerical values described using “to” means a range that includes numerical values listed before and after “to” as a lower limit and an upper limit.

[Thermoelectric Conversion Layer]

First, the characteristics of the thermoelectric conversion layer of the present invention will be described.

One of the characteristics of the thermoelectric conversion layer of the present invention is that the thermoelectric conversion layer contains a carbon nanotube (CNT)-containing n-type thermoelectric conversion material and a hydrogen bonding resin.

In a case where CNT in A thermoelectric conversion layer is exposed to the atmosphere, CNT changes to a p-type due to the oxygen in the atmosphere that functions as a dopant, and holes are made. It is considered that, as a result, in a case where CNT is used as an n-type thermoelectric conversion material, the electrons generated by the addition of a dopant for a change to an n-type to CNT are trapped in the aforementioned holes, and hence a power factor decreases.

Meanwhile, the inventors of the present invention obtained knowledge that the closer the CNT to each other in the thermoelectric conversion layer (in other words, the shorter the distance between a plurality of CNT), the higher the thermal conductivity of the thermoelectric conversion layer, and hence a thermoelectric conversion efficiency decreases.

The inventors of the present invention obtained knowledge that in a case where the thermoelectric conversion layer contains a hydrogen bonding resin, the aforementioned problem can be solved. The reason why the use of such a resin brings about the desired effect is unclear but is assumed to be as below.

It is considered that in the thermoelectric conversion layer, the hydrogen bonding resin may form a weak network by a hydrogen bonding functional group contained in the resin, and hence the intrusion of oxygen, which is a dopant for changing CNT into a p-type, into the system may be blocked. That is, due to the existence of the hydrogen bonding resin, CNT does not easily change to a p-type by oxygen, and the electrons, which are generated by doping in a case where CNT is used as an n-type thermoelectric conversion material, are prevented from trapped and deactivated. As a result, it is possible to obtain a thermoelectric conversion layer which demonstrates excellent performance as an n-type and has a high power factor.

Meanwhile, in the thermoelectric conversion layer, the hydrogen bonding resin also functions as a binder so as to increase the distance between CNT. Therefore, the obtained thermoelectric conversion layer has a low thermal conductivity and an excellent thermoelectric conversion efficiency. Particularly, in a case where a cellulose derivative is used as the hydrogen bonding resin, it is possible to obtain a thermoelectric conversion layer having a higher power factor and lower thermal conductivity.

It was confirmed that the thermoelectric conversion layer of the present invention exhibits excellent performance stability even being exposed to a high temperature for a long period of time.

As will be described later, the CNT-containing n-type thermoelectric conversion material may be constituted with CNT and a dopant for a change to an n-type. Generally, in a case where the dopant for a change to an n-type is exposed to a high temperature for a long period of time, even such a dopant (for example, particularly, an amine-based compound or a phosphine-based compound) tends to be easily oxidized due to the oxygen in the atmosphere. The oxidation of the dopant for a change to an n-type results in a decrease of a CNT doping efficiency, and at the same time, CNT easily changes to a p-type due to the oxygen in the atmosphere. Consequently, a Seebeck coefficient tends to decrease (in other words, the performance of an n-type tends to deteriorate).

In contrast, because the thermoelectric conversion layer of the present invention contains the hydrogen bonding resin, not only CNT but also the dopant for a change to an n-type are inhibited from being oxidized, and hence the thermoelectric conversion layer can maintain excellent performance stability even being exposed to a high temperature for a long period of time.

Hereinafter, each of the components contained in the thermoelectric conversion layer of the present invention will be described, and then a method for manufacturing the thermoelectric conversion layer of the present invention will be described.

[Carbon Nanotube-Containing n-Type Thermoelectric Conversion Material]

The constitution of the carbon nanotube (CNT)-containing n-type thermoelectric conversion material used in the present invention is not particularly limited as long as CNT is caused to function as an n-type thermoelectric conversion material.

Examples of the CNT-containing n-type thermoelectric conversion material usable in the present invention include a material obtained by mixing CNT with a dopant for a change to an n-type, nitrogen-doped CNT, and the like. The nitrogen-doped CNT is a material obtained by doping CNT with nitrogen by means of allowing a nitrogen source to coexist at the time of synthesizing CNT by a chemical vapor deposition (hereinafter, referred to as a “CVD” method as well).

Hereinafter, CNT and each of the components of the dopant for a change to an n-type will be specifically described.

<Carbon Nanotubes>

Carbon nanotubes (CNT) include single-layer CNT formed of one sheet of carbon film (graphene sheet) wound in the form of a cylinder, double-layered CNT formed of two graphene sheets wound in the form of concentric circles, and multilayered CNT formed of a plurality of graphene sheets wound in the form of concentric circles. In the present invention, one kind of each of the single-layer CNT, the double-layered CNT, and the multilayered CNT may be used singly, or two or more kinds thereof may be used in combination. Particularly, the single-layer CNT having excellent properties in terms of electric conductivity and semiconductor characteristics and the double-layered CNT are preferably used, and the single-layer CNT is more preferably used.

The single-layer CNT may be semiconductive or metallic, and both of semiconductive CNT and metallic CNT may be used in combination. Furthermore, CNT may contain a metal or the like, and CNT containing a fullerene molecule and the like (particularly, CNT containing fullerene is called a pivot) may be used.

CNT can be manufactured by an arc discharge method, a CVD method, a laser⋅ablation method, and the like. CNT used in the present invention may be obtained by any method, but it is preferable to use CNT obtained by the arc discharge method and the CVD method.

At the time of manufacturing CNT, fullerene or graphite and amorphous carbon are also generated as by-products in some cases. In order to remove these by-products, CNT may be purified. The CNT purification method is not particularly limited, and examples thereof include methods such as washing, centrifugation, filtration, oxidation, and chromatography. In addition, an acid treatment using nitric acid, sulfuric acid, and the like and an ultrasonic treatment are also effective for removing impurities. Furthermore, from the viewpoint of improving purity, it is more preferable to separate and remove impurities by using a filter.

CNT obtained after purification may be used as it is. Furthermore, because of being generated in the form of strings in general, CNT may be used after being cut in the desired length according to the purpose. By an acid treatment using nitric acid, sulfuric acid, or the like, an ultrasonic treatment, a freezing and pulverizing method, and the like, CNT can be cut in the form of short fiber. From the viewpoint of improving purity, it is also preferable to collectively separate CNT by using a filter.

In the present invention, not only cut CNT but also CNT prepared in the form of short fiber can also be used.

The average length of CNT is not particularly limited. However, from the viewpoint of ease of manufacturing, film formability, electric conductivity, and the like, the average length is preferably 0.01 to 1,000 μm, and more preferably 0.1 to 100 μm.

The diameter of the single-layer CNT is not particularly limited. From the viewpoint of durability, film formability, electric conductivity, thermoelectric performance, and the like, the diameter of the single-layer CNT is preferably equal to or greater than 0.5 nm and equal to or smaller than 4.0 nm, more preferably equal to or greater than 0.6 nm and equal to or smaller than 3.0 nm, and even more preferably equal to or greater than 0.7 nm and equal to or smaller than 2.0 nm. The diameter distribution of 70% or more of CNT (hereinafter, “diameter distribution of 70% or more” will be simply described as “diameter distribution” as well) is preferably within 3.0 nm, more preferably within 2.0 nm, even more preferably within 1.0 nm, and particularly preferably within 0.7 nm.

The diameter and the diameter distribution can be measured by the method which will be described later.

Sometimes the used CNT includes defective CNT. The defect of CNT results in the deterioration of the electric conductivity of a dispersion for a thermoelectric conversion layer and the like. Therefore, it is preferable to reduce the defect. The amount of the defect of CNT can be estimated by an intensity ratio G/D (hereinafter, referred to as a G/D ratio) between a G-band and a D-band in a Raman spectrum. In a case where a CNT material has a high G/D ratio, the material can be estimated as having a small amount of defects. Particularly, in a case where single-layer CNT is used, the G/D ratio is preferably equal to or higher than 10 and more preferably equal to or higher than 30.

[Calculation of Diameter and Diameter Distribution of Single-Layer CNT]

In the present specification, the diameter of single-layer CNT is evaluated by the following method. That is, a Raman spectrum of the single-layer CNT is measured using excitation light of 532 nm (excitation wavelength: 532 nm), and by a shift ω (RBM) (cm⁻¹) of a radial breathing mode (RBM), the diameter of the single-layer CNT is calculated using the following calculation formula. The value calculated from a maximum peak was taken as the diameter of CNT. The diameter distribution was obtained from the distribution of each peak top.

Calculation formula: Diameter (nm)=248/ω (RBM)

From the viewpoint of the thermoelectric conversion performance, the content of CNT in the thermoelectric conversion layer with respect to the total solid content in the thermoelectric conversion layer is preferably 5% to 95% by mass, more preferably 30% to 90% by mass, and particularly preferably 40% to 80% by mass.

One kind of CNT may be used singly, or two or more kinds of CNT may be used in combination.

The aforementioned solid content means the components forming the thermoelectric conversion layer and does not include a solvent and a dispersant.

<Dopant for Change to n-Type>

The dopant for a change to an n-type is not particularly limited as long as the dopant can change CNT into an n-type by reducing CNT or donating electrons to CNT, and known compounds can be used.

As the dopant for a change to an n-type, for example, it is possible to use a reducing substance, an electron donor compound, and the like including an amine-based compound such as ammonia, tetramethyl phenylenediamine, stearylamine, or tribenzylamine, an imine compound such as polyethyleneimine, an alkali metal such as potassium, a phosphine-based compound such as triphenylphosphine, trioctylphosphine, or 1,3-bis(diphenylphosphine)propane, a metal hydride such as sodium borohydride or lithium aluminum hydride, hydrazine, cobaltocene, ferrocene, and 2-(2-methoxyphenyl)-1,3-dimethyl-2,3-dihydro-1H-benzo [d] imidazole. Specifically, it is possible to use known compounds described in Scientific Reports 3, 3344.

In addition to the aforementioned compounds, a polyoxyalkylene-based compound can also be used.

The structure of the polyoxyalkylene-based compound is not particularly limited as long as the compound has a polyalkylene oxide structure. Examples of preferred alkylene oxides include ethylene oxide, propylene oxide, a mixture of these, and the like.

Examples of the polyoxyalkylene-based compound usable in the present invention include a polyethylene glycol-type higher alcohol ethylene oxide adduct, an ethylene oxide adduct of phenol, naphthol, or the like, a fatty acid ethylene oxide adduct, a polyhydric alcohol fatty acid ester ethylene oxide adduct, a higher alkylamine ethylene oxide adduct, a fatty acid amide ethylene oxide adduct, an ethylene oxide adduct of fat and oil, a polypropylene glycol ethylene oxide adduct, a dimethyl siloxane-ethylene oxide block copolymer, a dimethylsiloxane-(propylene oxide-ethylene oxide) block copolymer, and the like. Among these, a fatty acid ethylene oxide adduct, a higher alcohol ethylene oxide adduct, and a polypropylene glycol ethylene oxide adduct can be preferably used, and a higher alcohol ethylene oxide adduct is particularly preferable.

Examples of the polyoxyalkylene-based compound usable in the present invention include the compounds shown below. Here, the number of polyoxyalkylene group units is not limited to the specific examples shown below and can be any integer.

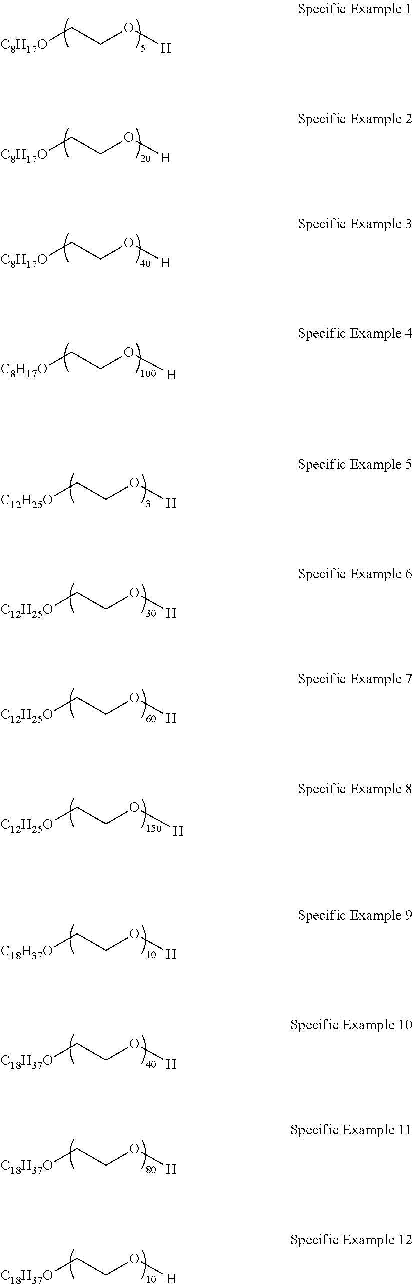

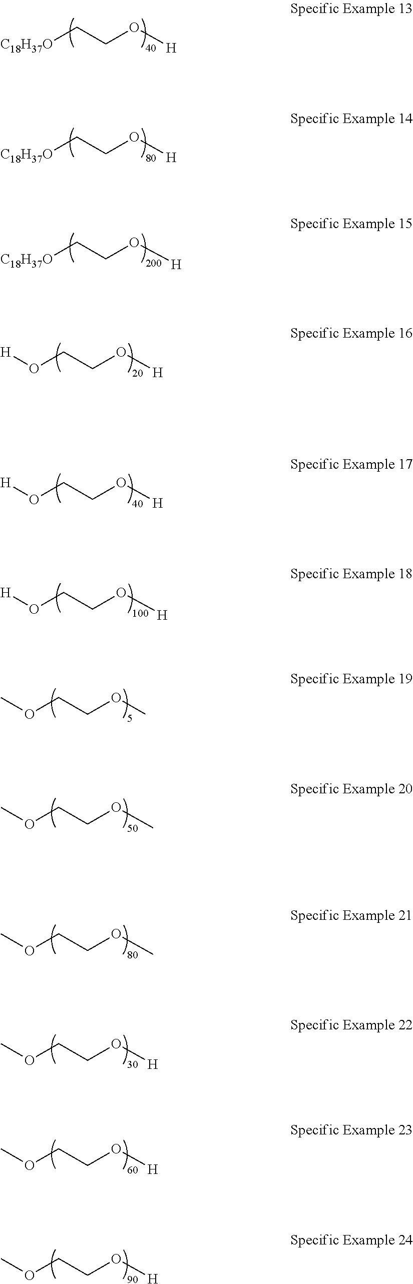

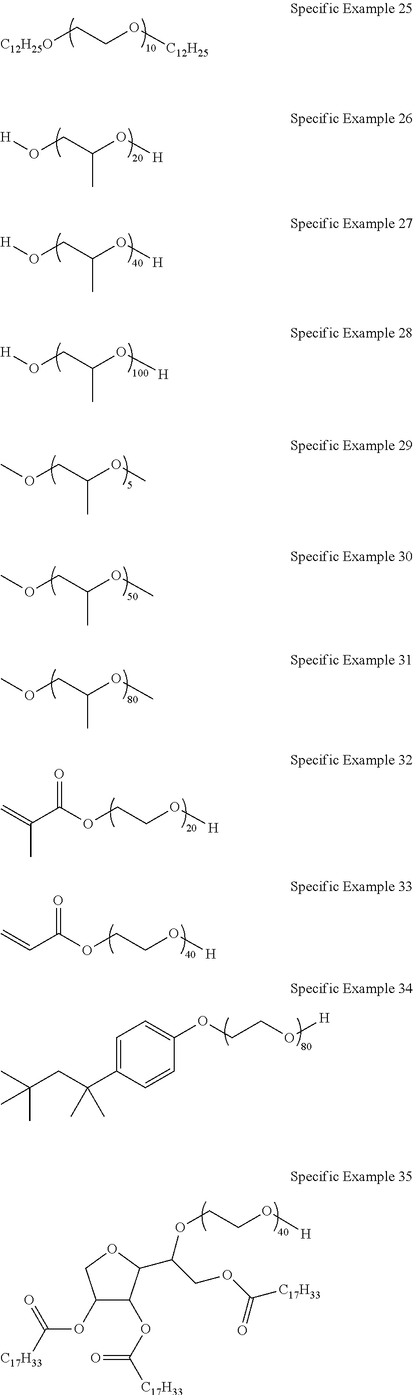

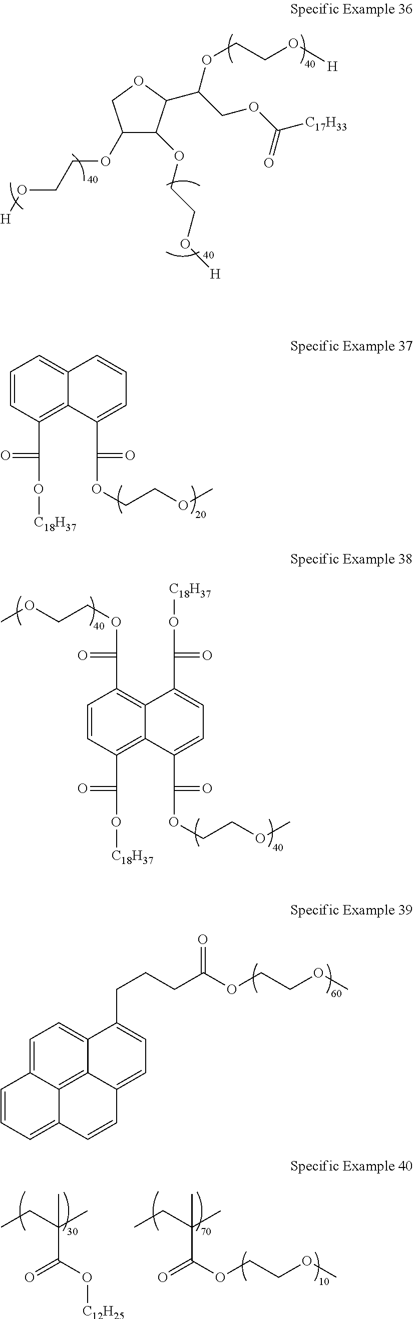

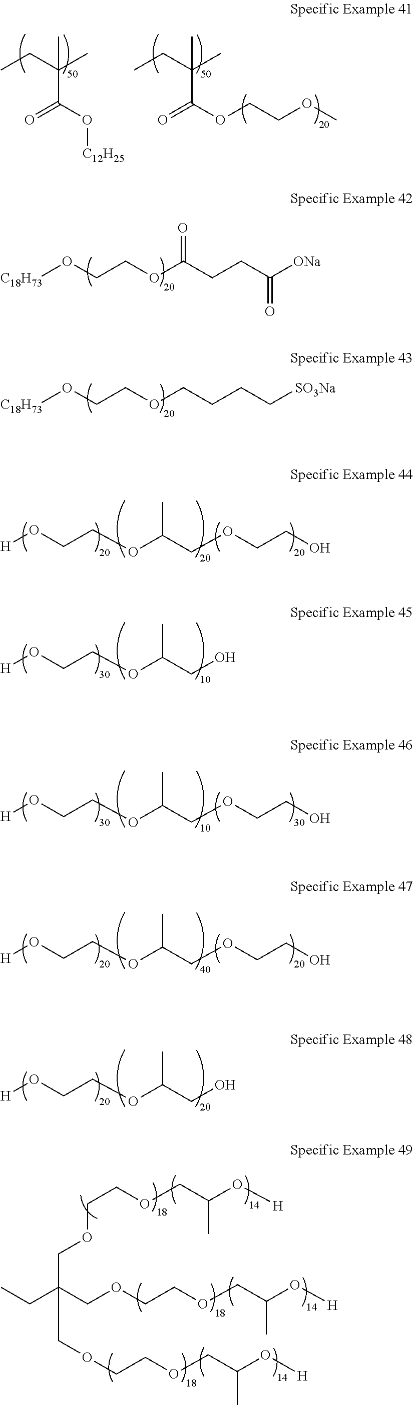

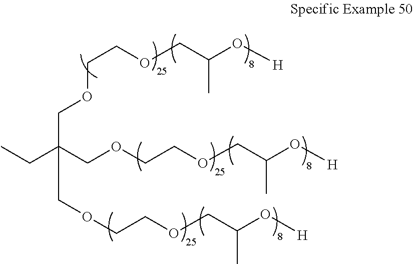

As the dopant for a change to an n-type, among the above compounds, from the viewpoint of obtaining a higher power factor and causing the thermoelectric conversion layer to exhibit higher performance stability even being exposed to a high temperature for a long period of time, at least one kind of compound selected from the group consisting of a polyoxyalkylene-based compound, an amine-based compound, and a phosphine-based compound is preferable, and a polyoxyalkylene-based compound is more preferable.

In the CNT-containing n-type thermoelectric conversion material, the content of the dopant for a change to an n-type with respect to the content of CNT is preferably 7% to 200% by mass. From the viewpoint of further improving the thermoelectric conversion performance (particularly, a power factor), the content of the dopant for a change to an n-type with respect to the content of CNT is preferably 12% to 150% by mass and particularly preferably 20% to 100% by mass.

The method for preparing the CNT-containing n-type thermoelectric conversion material by mixing the dopant for a change to an n-type with CNT is not particularly limited, and the CNT-containing n-type thermoelectric conversion material can be prepared by known methods.

[Hydrogen Bonding Resin]

The hydrogen bonding resin usable in the present invention means a resin having a functional group that can form a hydrogen bond (hereinafter, referred to as “hydrogen bonding functional group” as well), and the structure thereof is not particularly limited.

Examples of the hydrogen bonding functional group include a OH group, an NH₂ group, an NHR group (R represents an aromatic or aliphatic hydrocarbon group), a COOH group, a CONH₂ group, an NHOH group, a SO₃H group (sulfonic acid group), a —OP(═O)OH₂ group (phosphoric acid group), and a group having —NHCO—, —NH—, —CONHCO—, —NH—NH—, —C(═O)— (carbonyl group), —ROR— (ether group: R each independently represents divalent aromatic hydrocarbon or divalent aliphatic hydrocarbon. Here, two R's may be the same as or different from each other), and the like.

Examples of resins having a hydrogen bonding functional group include carboxymethyl cellulose, carboxyethyl cellulose, methyl cellulose, ethyl cellulose, hydroxymethyl cellulose, hydroxyethyl cellulose, hydroxypropyl methylcellulose, crystalline cellulose, xanthan gum, guar gum, hydroxyethyl guar gum, carboxymethyl guar gum, gum tragacanth, locust bean gum, tamarind seed gum, psyllium seed gum, quince seeds, galactan, gum Arabic, pectin, pullulan, mannan, glucomannan, carrageenan, chondroitin sulfate, dermatan sulfate, glycogen, heparan sulfate, hyaluronic acid, keratin sulfate, chondroitin, mucoitin sulfate, dextran, keratosulfate, succinoglucan, charonin sulfate, alginic acid, propylene glycol alginate, macrogol, chitin, chitosan, carboxymethyl chitin, gelatin, agar, curdlan, polyvinyl alcohol, polyvinyl pyrrolidone, a carboxyvinyl polymer, an alkyl-modified carboxyvinyl polymer, polyacrylic acid, an acrylic acid/alkyl methacrylate copolymer, polyacrylonitrile, a (hydroxyethyl acrylate/sodium acryloyldimethyltaurate) copolymer, an (ammonium acryloyldimethyltaurate/vinyl pyrrolidone) copolymer, nylon, polyethylene terephthalate, starch, chemically modified starch, bentonite, xylan, and the like.

In a case where the hydrogen bonding functional group is an acidic group such as a carboxyl group, the hydrogen bonding functional group may totally or partially become a salt such as a sodium salt, a potassium salt, or an ammonium salt.

As the hydrogen bonding resin, among the above resins, from the viewpoint of a higher power factor and causing the thermoelectric conversion layer to exhibit excellent performance stability even being exposed to a high temperature for a long period of time, a polysaccharide is preferable, and a polysaccharide having a carboxyl group or a salt thereof is more preferable. From the viewpoint of further improving other thermoelectric conversion performances such as a Seebeck coefficient, a cellulose derivative is particularly preferable as the hydrogen bonding resin.

The weight-average molecular weight of the hydrogen bonding resin is not particularly limited. However, from the viewpoint of dispersion stability, the weight-average molecular weight is preferably 1,000 to 1,200,000, and more preferably 1,000 to 800,000. The weight-average molecular weight of the hydrogen bonding resin can be checked by gel permeation chromatography (GPC).

More specifically, regarding the GPC measurement method, an object is dissolved in 100 mM aqueous sodium nitrate solution, and by using a high-performance GPC device (for example, HLC-8220GPC (manufactured by Tosoh Corporation)), the weight-average molecular weight thereof can be calculated and expressed in terms of polyethylene oxide. The conditions of the GPC measurement are as below.

Column: manufactured by Tosoh Corporation TSKGEL G5000PWXL
TSKGEL G4000PWXL
TSKGEL G2500PWXL

Column temperature: 40° C.

Flow rate: 1 mL/min

Eluent: 100 mM aqueous sodium nitrate solution

In the thermoelectric conversion layer, the content of the hydrogen bonding resin is preferably 2% to 80% by mass with respect to the content of CNT. In a case where the content of the hydrogen bonding resin is within the above range, it is possible to obtain a thermoelectric conversion layer which has a higher power factor and a lower thermal conductivity and exhibits higher performance stability even being exposed to a high temperature for a long period of time.

In the thermoelectric conversion layer, the content of the hydrogen bonding resin with respect the content of CNT is more preferably 7% to 70% by mass, even more preferably 12% to 70% by mass, particularly preferably 12% to 50% by mass, and most preferably 13% to 50% by mass.

In the thermoelectric conversion layer, a mixing ratio between the aforementioned hydrogen bonding resin and the dopant for a change to an n-type (hydrogen bonding resin/dopant for a change to an n-type) that is represented by a mass ratio is preferably 1/80 to 10/1, more preferably 1/20 to 5/1, even more preferably 1/8 to 2/1, and particularly preferably 1/4 to 2/1.

[Optional Components]

The thermoelectric conversion layer of the present invention may contain other components (a dispersion medium, a polymer compound, a surfactant, an antioxidant, a lightfast stabilizer, a heat-resistant stabilizer, a plasticizer, and the like) in addition to the CNT-containing n-type thermoelectric conversion material and the hydrogen bonding resin described above. The definition, the specific examples, and the suitable aspect of each of the components are the same as those of each of the components contained in the composition for forming a thermoelectric conversion layer that will be described later.

[Method for Manufacturing Thermoelectric Conversion Layer]

The method for manufacturing the thermoelectric conversion layer is not particularly limited, and examples thereof include a first suitable aspect, a second suitable aspect, and the like described below.

<First Suitable Aspect>

The first suitable aspect of the method for manufacturing the thermoelectric conversion layer is a method of using a composition for forming a thermoelectric conversion layer containing a CNT-containing n-type thermoelectric conversion material and a hydrogen bonding resin.

First, the composition will be described, and then the manufacturing method will be described.

(Composition for Forming Thermoelectric Conversion Layer)

As described above, the composition for forming a thermoelectric conversion layer contains a CNT-containing n-type thermoelectric conversion material and a hydrogen bonding resin.

First, each of the components contained in the composition will be described, and then the method for preparing the composition will be described.

In the first suitable aspect which will be described below, an example will be described in which a CNT-containing n-type thermoelectric conversion material containing CNT and a dopant for a change to an n-type is used. However, it goes without saying that even in a case where nitrogen-doped CNT is used, the thermoelectric conversion layer can be formed by the same method.

(1) Carbon Nanotubes (CNT)

The definition, the specific examples, and the suitable aspect of CNT are as described above. The content of the carbon nanotubes in the composition for forming a thermoelectric conversion layer is not particularly limited, but is preferably 0.1% to 20% by mass and more preferably 1% to 10% by mass with respect to the total amount of the composition.

(2) Dopant for Change to n-Type

The definition, the specific examples, and the suitable aspect of the dopant for a change to an n-type are as described above. The content of the dopant for a change to an n-type in the composition for forming a thermoelectric conversion layer is not particularly limited, but is preferably 0.05% to 20% by mass and more preferably 0.1% to 10% by mass with respect to the total amount of the composition.

(3) Hydrogen Bonding Resin

The definition, the specific examples, and the suitable aspect of the hydrogen bonding resin are as described above. The content of the hydrogen bonding resin in the composition for forming a thermoelectric conversion layer is not particularly limited, but is preferably 0.05% to 20% by mass and more preferably 0.05% to 10% by mass with respect to the total amount of the composition.

In the composition, the aforementioned mixing ratio between the hydrogen bonding resin and the dopant for a change to an n-type (hydrogen bonding resin/dopant for a change to an n-type) that is represented by a mass ratio is preferably 1/80 to 10/1, more preferably 1/20 to 5/1, even more preferably 1/8 to 2/1, and particularly preferably 1/4 to 2/1.

(4) Dispersion Medium

It is preferable that the composition for forming a thermoelectric conversion layer contains a dispersion medium in addition to CNT and the hydrogen bonding resin.

The dispersion medium (solvent) is not limited as long as it can disperse CNT, and water, an organic solvent, and a mixed solvent of these can be used. Examples of the organic solvent include an alcohol-based solvent, an aliphatic halogen-based solvent such as chloroform, an aprotic polar solvent such as dimethylformamide (DMF), N-methylpyrrolidone (NMP), or dimethylsulfoxide (DMSO), an aromatic solvent such as chlorobenzene, dichlorobenzene, benzene, toluene, xylene, mesitylene, tetralin, tetramethylbenzene, or pyridine, a ketone-based solvent such as cyclohexanone, acetone, or methyl ethyl ketone, an ether-based solvent such as diethylether, tetrahydrofuran (THF), t-butylmethylether, dimethoxyethane, or diglyme, and the like.

One kind of dispersion medium can be used singly, or two or more kinds thereof can be used in combination.

It is preferable that the dispersion medium has undergone deaeration. A dissolved oxygen concentration in the dispersion medium is preferably equal to or lower than 10 ppm. Examples of the deaeration method include a method of irradiating the dispersion medium with ultrasonic waves under reduced pressure, a method of performing bubbling using an inert gas such as argon, and the like.

In a case where a solvent other than water is used as the dispersion medium, it is preferable to perform deaeration in advance. A moisture amount in the dispersion medium is preferably equal to or less than 1,000 ppm, and more preferably equal to or less than 100 ppm. As the deaeration method for the dispersion medium, it is possible to use known methods such as a method using a molecular sieve and distillation.

The content of the dispersion medium in the composition for forming a thermoelectric conversion layer with respect to the total amount of the composition is preferably 25% to 99.99% by mass, more preferably 30% to 99.95% by mass, and even more preferably 30% to 99.9% by mass.

As the dispersion medium, water or an alcohol-based solvent which has a C log P value equal to or smaller than 3.0 is suitably exemplified, because these excellently disperse CNT and further improve the characteristics (electric conductivity and thermoelectromotive force) of the thermoelectric conversion layer. The C log P value will be specifically described later.

The alcohol-based solvent means a solvent containing a —OH group (hydroxy group).

The C log P value of the alcohol-based solvent is equal to or smaller than 3.0. The C log P value is preferably equal to or smaller than 1.0, because then the CNT dispersibility is further improved, and the characteristics of the thermoelectric conversion element are further improved. The lower limit of the C log P value is not particularly limited. In view of the aforementioned effects, the lower limit is preferably equal to or greater than −3.0, more preferably equal to or greater than −2.0, and even more preferably equal to or greater than −1.0.

(C Log P Value)

A log P value is a common logarithm of a partition coefficient P. It is a physical property value showing how a certain compound is partitioned in equilibrium of two phase system consisting of oil (herein, n-octanol) and water by using a quantitative numerical value. The greater the log P value, the more the compound is hydrophobic, and the smaller the log P value, the more the compound is hydrophilic. Therefore, the log P value can be used as a parameter showing hydrophilicity and hydrophobicity of a compound.

log P=log(Coil/Cwater)

Coil=molar concentration in oil phase

Cwater=molar concentration in water phase

Although the log P value can be generally experimentally determined using n-octanol and water, in the present invention, a partition coefficient (C log P value) (calculated value) determined using a log P value estimation program is used. Specifically, in the present specification, a C log P value determined using “ChemBioDraw ultra ver. 12” is used.

(5) Other Components

The composition for forming a thermoelectric conversion layer may contain a polymer compound, a surfactant, an antioxidant, a lightfast stabilizer, a heat-resistant stabilizer, a plasticizer, and the like in addition to the components described above.

Examples of the polymer compound include a conjugated polymer and a non-conjugated polymer.

Examples of the surfactant include known surfactants (a cationic surfactant, an anionic surfactant, and the like). Among these, an anionic surfactant is preferable, and sodium cholate and sodium deoxycholate are more preferable.

Examples of the antioxidant include IRGANOX 1010 (manufactured by Ciba-Geigy Japan Limited), SUMILIZER GA-80 (manufactured by Sumitomo Chemical Co., Ltd.), SUMILIZER GS (manufactured by Sumitomo Chemical Co., Ltd), SUMILIZER GM (manufactured by Sumitomo Chemical Co., Ltd.), and the like.

Examples of the lightfast stabilizer include TINUVIN 234 (manufactured by BASF SE), CHIMASS ORB 81 (manufactured by BASF SE), CYASORB UV-3853 (manufactured by SUN CHEMICAL COMPANY LTD.), and the like.

Examples of the heat-resistant stabilizer include IRGANOX 1726 (manufactured by BASF SE).

Examples of the plasticizer include ADEKASIZER RS (manufactured by ADEKA Corporation) and the like.

The content rate of the components other than the aforementioned dispersion medium with respect to the total amount of the composition is preferably 0.1% to 20% by mass, and more preferably 1% to 10% by mass.

(Method for Preparing Composition for Forming Thermoelectric Conversion Layer)

The composition for forming a thermoelectric conversion layer can be prepared by mixing the aforementioned components together. It is preferable that the composition is prepared by mixing together a dispersion medium, CNT as a CNT-containing n-type thermoelectric conversion material, a dopant for a change to an n-type, a hydrogen bonding resin, and other components which are used if necessary, and dispersing CNT.

In the first suitable aspect, an example was described in which the composition is prepared by separately adding CNT and the dopant for a change to an n-type which are components constituting the CNT-containing n-type thermoelectric conversion material as described above. However, it goes without saying that an aspect may be adopted in which a mixture of CNT and the dopant for a change to an n-type is prepared in advance as the CNT-containing n-type thermoelectric conversion material and then introduced into the composition.

The method for preparing the composition is not particularly limited and can be performed using a general mixing device or the like at room temperature and normal pressure. For example, the composition may be prepared by dissolving or dispersing the respective components in a solvent by stirring, shaking, or kneading. In order to accelerate the dissolution or dispersion, an ultrasonic treatment may be performed.

Furthermore, it is possible to improve the dispersibility of carbon nanotubes by means of heating the solvent to a temperature that is equal to or higher than room temperature and equal to or lower than a boiling point in the aforementioned dispersion step, extending the dispersion time, increasing the strength applied at the time of stirring, shaking, or kneading and the intensity of ultrasonic waves, and the like.

(Manufacturing Method)

The method for manufacturing the thermoelectric conversion layer by using the composition for forming a thermoelectric conversion layer is not particularly limited, and examples thereof include a method of coating a substrate with the composition and forming a film, and the like.

The film forming method is not particularly limited, and it is possible to use known coating methods such as a spin coating method, an extrusion die coating method, a blade coating method, a bar coating method, a screen printing method, a stencil printing method, a metal mask printing method, a roll coating method, a curtain coating method, a spray coating method, a dip coating method, and an ink jet method.

If necessary, a drying step is performed after coating. For example, by exposing the film to the hot air, a solvent can be volatilized and dried.

<Second Suitable Aspect>

The second suitable aspect of the method for manufacturing the thermoelectric conversion layer is a method in which a thermoelectric conversion layer precursor is prepared using a composition for forming a thermoelectric conversion layer precursor containing CNT and a hydrogen bonding resin, the aforementioned dopant for a change to an n-type is applied to the thermoelectric conversion layer precursor such that the CNT-containing n-type thermoelectric conversion material is constituted, and CNT is changed to an n-type through doping.

First, the composition will be described, and then the manufacturing method will be described.

(Composition for Forming Thermoelectric Conversion Layer Precursor)

As described above, the composition for forming a thermoelectric conversion layer precursor contains CNT and a hydrogen bonding resin. The definitions, the specific examples, and the suitable aspects of CNT and the hydrogen bonding resin are as described above. A suitable aspect of the content of CNT and the hydrogen bonding resin in the composition is the same as that in the first suitable aspect described above.

It is preferable that the composition for forming a thermoelectric conversion layer precursor contains a dispersion medium in addition to CNT and the hydrogen bonding resin. The specific examples and the suitable aspects of the dispersion medium are the same as those in the first suitable aspect described above.

Furthermore, the composition for forming a thermoelectric conversion layer precursor may contain other components. The specific examples and the suitable aspects of the aforementioned other components are the same as those in the first suitable aspect.

(Manufacturing Method)

The method for manufacturing a thermoelectric conversion layer precursor by using the composition for forming a thermoelectric conversion layer precursor is not particularly limited, and the specific examples and the suitable aspects of the method are the same as those in the method for manufacturing the thermoelectric conversion layer in the first suitable aspect described above.

In a second suitable aspect, a thermoelectric conversion layer precursor is prepared, and then CNT is changed to an n-type through doping by using the aforementioned dopant for a change to an n-type. In this way, a thermoelectric conversion layer is obtained.

The change to an n-type through doping is not particularly limited as long as it is a method of using a dopant for a change to an n-type. Examples thereof include a method of immersing the thermoelectric conversion layer precursor in a solution obtained by dissolving the aforementioned dopant for a change to an n-type in a solvent. Specific examples of the solvent are the same as those of the dispersion medium described above.

If necessary, a drying step may be performed after the change to an n-type through doping. For example, by exposing the thermoelectric conversion layer to the hot air, the solvent can be volatilized and dried.

[Thickness]

From the viewpoint of causing a temperature difference and the like, the average thickness of the thermoelectric conversion layer of the present invention is preferably 1 to 500 μm, more preferably 2 to 300 μm, even more preferably 3 to 200 μm, and particularly preferably 5 to 100 μm.

The average thickness of the thermoelectric conversion layer can be determined by measuring thicknesses of the thermoelectric conversion layer at 10 random points and calculating an arithmetic mean thereof.

[Thermoelectric Conversion Element]

The constitution of the thermoelectric conversion element of the present invention is not particularly limited as long as the thermoelectric conversion element includes the thermoelectric conversion layer of the present invention described above. It is preferable that the thermoelectric conversion element of the present invention includes the thermoelectric conversion layer of the present invention described above as an n-type thermoelectric conversion layer.

Hereinafter, suitable aspects of the thermoelectric conversion element of the present invention, in which the thermoelectric conversion layer of the present invention is used as an n-type thermoelectric conversion layer, will be specifically described.

In the following description, the thermoelectric conversion layer of the present invention will be simply referred to as “n-type thermoelectric conversion layer”.

In the thermoelectric conversion element of the present invention, the thermoelectric conversion layer may include only the aforementioned n-type thermoelectric conversion layer or include, in addition to the n-type thermoelectric conversion layer, a p-type thermoelectric conversion layer (preferably a CNT-containing p-type thermoelectric conversion layer) electrically connected to the n-type thermoelectric conversion layer. As long as both the n-type thermoelectric conversion layer and the p-type thermoelectric conversion layer are electrically connected to each other, the thermoelectric conversion layers may come into direct contact with each other, or a conductor (for example, an electrode) may be disposed between them.

### First Embodiment

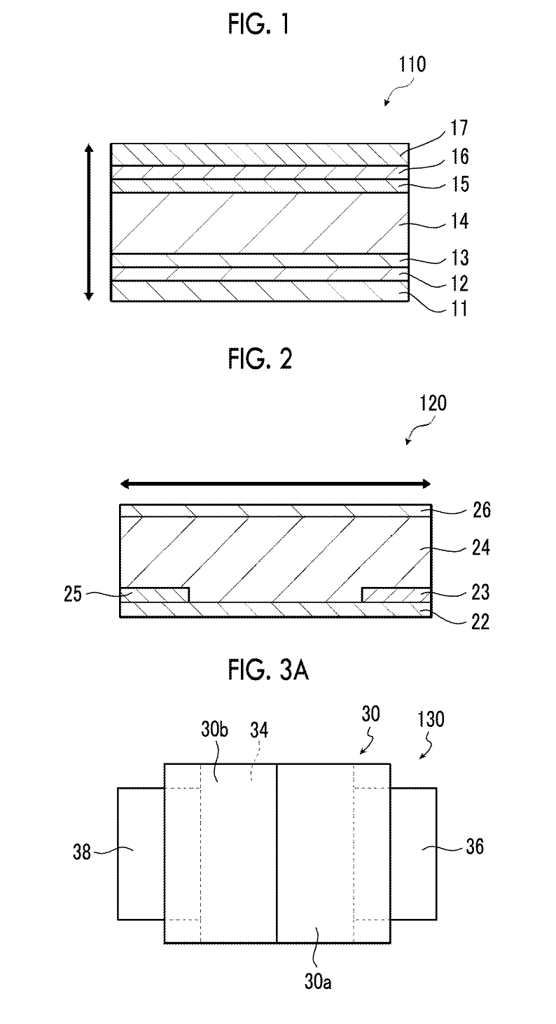

FIG. 1 is a cross-sectional view of a first embodiment of the thermoelectric conversion element of the present invention.

In a thermoelectric conversion element 110 shown in FIG. 1, a pair of electrodes which includes a first electrode 13 and a second electrode 15 is disposed on a first substrate 12, and between the first electrode 13 and the second electrode 15, there is an n-type thermoelectric conversion layer 14 which contains a CNT-containing n-type thermoelectric conversion material and a hydrogen bonding resin. On the other surface of the second electrode 15, a second substrate 16 is disposed. On the outside of the first substrate 12 and the second substrate 16, metal plates 11 and 17 facing each other are disposed.

### Second Embodiment

FIG. 2 is a cross-sectional view of a second embodiment of the thermoelectric conversion element of the present invention.

In a thermoelectric conversion element 120 shown in FIG. 2, a first electrode 23 and a second electrode 25 are disposed on a first substrate 22, and an n-type thermoelectric conversion layer 24, which contains a CNT-containing n-type thermoelectric conversion material and a hydrogen bonding resin, is provided on the electrodes. The other surface of the n-type thermoelectric conversion layer 24 is provided with a second substrate 26.

### Third Embodiment

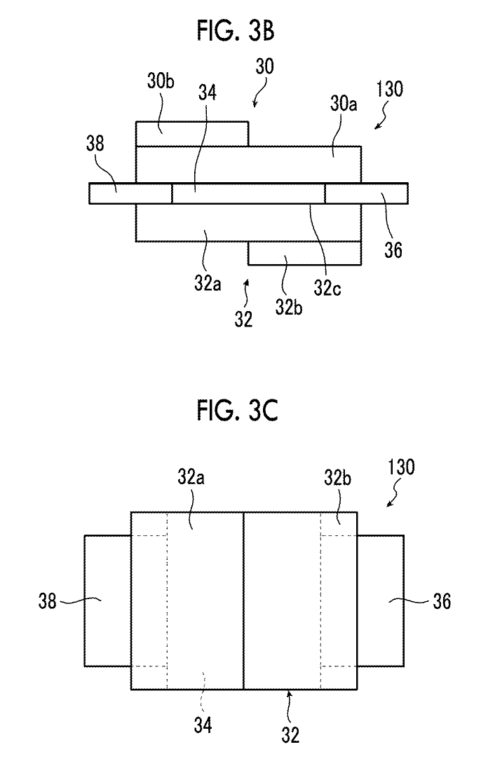

FIGS. 3A to 3C conceptually show a third embodiment of the thermoelectric conversion element of the present invention. FIG. 3A is a top view (a drawing obtained in a case where FIG. 3B is viewed from above the paper), FIG. 3B is a front view (a drawing obtained in a case where the thermoelectric conversion element is viewed from the plane direction of a substrate, which will be described later, and the like), and FIG. 3C is a bottom view (a drawing obtained in a case where FIG. 3B is viewed from the bottom of the paper).

As shown in FIGS. 3A to 3C, a thermoelectric conversion element 130 is basically constituted with a first substrate 32, an n-type thermoelectric conversion layer 34 containing a CNT-containing n-type thermoelectric conversion material and a hydrogen bonding resin, a second substrate 30, a first electrode 36, and a second electrode 38.

Specifically, on a surface of the first substrate 32, the n-type thermoelectric conversion layer 34 is formed. Furthermore, on the surface of the first substrate 32, the first electrode 36 and the second electrode 38 (electrode pair) are formed which contact the n-type thermoelectric conversion layer 34 interposed between the electrodes in a substrate surface direction of the first substrate 32 (hereinafter, the substrate surface direction will be simply referred to as “plane direction” as well which is in other words a direction orthogonal to the direction along which the first substrate 32 and the second substrate 30 are laminated).

A pressure sensitive adhesive layer may be disposed between the first substrate 32 and the n-type thermoelectric conversion layer 34 or between the second substrate 30 and the n-type thermoelectric conversion layer 34, although the pressure sensitive adhesive layer is not shown in FIGS. 3A to 3C.

As shown in FIGS. 3A to 3C, the first substrate 32 includes a low thermal conduction portion 32a and a high thermal conduction portion 32b having a thermal conductivity higher than that of the low thermal conduction portion 32a. Likewise, the second substrate 30 includes a low thermal conduction portion 30a and a high thermal conduction portion 30b having a thermal conductivity higher than that of the low thermal conduction portion 30a.

In the thermoelectric conversion element 130, the two substrates are disposed such that the high thermal conduction portions thereof are in different positions in a direction along which the first electrode 36 and the second electrode 38 are separated from each other (that is, a direction along which electricity is conducted).

In a preferred aspect, the thermoelectric conversion element 130 has the second substrate 30 bonded through a pressure sensitive adhesive layer, and both the first substrate 32 and the second substrate 30 have a low thermal conduction portion and a high thermal conduction portion. The thermoelectric conversion element 130 has a constitution in which two sheets of substrates each having a high thermal conduction portion and a low thermal conduction portion are used such that the thermoelectric conversion layer is interposed between the two sheets of substrates in a state where the high thermal conduction portions of the two substrates are in different positions in the plane direction.

That is, the thermoelectric conversion element 130 is a thermoelectric conversion element which converts heat energy into electric energy by causing a temperature difference in the plane direction of the thermoelectric conversion layer (hereinafter, the thermoelectric conversion element will be referred to as an in plane-type thermoelectric conversion element as well). In the example illustrated in the drawing, by using a substrate including a low thermal conduction portion and a high thermal conduction portion having a thermal conductivity higher than that of the low thermal conduction portion, a temperature difference can be caused in the plane direction of the n-type thermoelectric conversion layer 34, and heat energy can be converted into electric energy.

### Fourth Embodiment

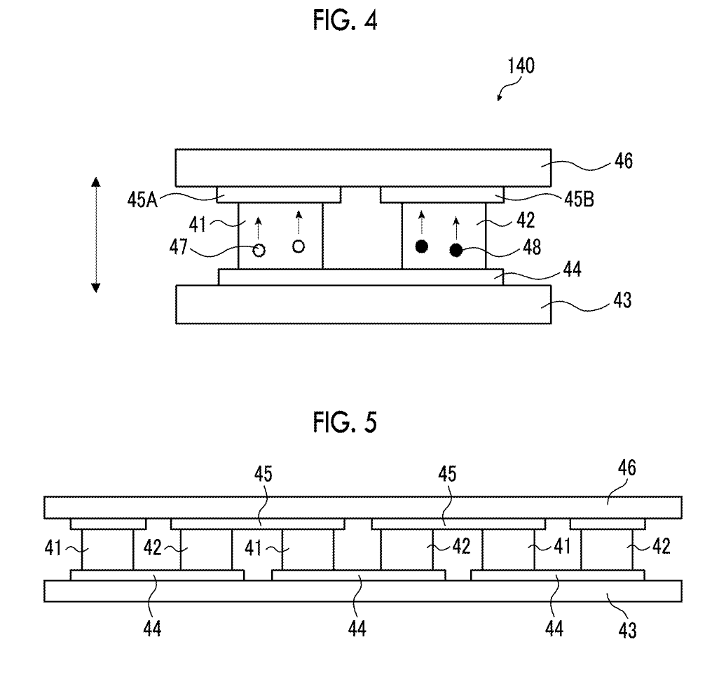

FIG. 4 conceptually shows a fourth embodiment of the thermoelectric conversion element.

A thermoelectric conversion element 140 shown in FIG. 4 has a p-type thermoelectric conversion layer (p-type thermoelectric conversion portion) 41 and an n-type thermoelectric conversion layer (n-type thermoelectric conversion portion) 42, and these layers are disposed in parallel to each other. The n-type thermoelectric conversion layer 42 is an n-type thermoelectric conversion layer containing a CNT-containing n-type thermoelectric conversion material and a hydrogen bonding resin. The constitution of each of the p-type thermoelectric conversion layer 41 and the n-type thermoelectric conversion layer 42 will be specifically described later.

An upper end portion of the p-type thermoelectric conversion layer 41 is electrically and mechanically connected to a first electrode 45A, and an upper end portion of the n-type thermoelectric conversion layer 42 is electrically and mechanically connected to a third electrode 45B. On the outside of the first electrode 45A and the third electrode 45B, an upper substrate 46 is disposed. A lower end portion of each of the p-type thermoelectric conversion layer 41 and the n-type thermoelectric conversion layer 42 is electrically and mechanically connected to a second electrode 44 supported on a lower substrate 43. In this way, the p-type thermoelectric conversion layer 41 and the n-type thermoelectric conversion layer 42 are connected to each other in series through the first electrode 45A, the second electrode 44, and the third electrode 45B. That is, the p-type thermoelectric conversion layer 41 and the n-type thermoelectric conversion layer 42 are electrically connected to each other through the second electrode 44.

The thermoelectric conversion element 140 makes a temperature difference (in the direction of the arrow in FIG. 4) between the upper substrate 46 and the lower substrate 43, and as a result, for example, the upper substrate 46 side becomes a low-temperature portion, and the lower substrate 43 side becomes a high-temperature portion. In a case where such a temperature difference is made, in the p-type thermoelectric conversion layer 41, a hole 47 carrying a positive charge moves to the low-temperature portion side (upper substrate 46 side), and the potential of the first electrode 45A becomes higher than that of the second electrode 44. In contrast, in the n-type thermoelectric conversion layer 42, an electrode 48 carrying a negative charge moves to the low-temperature portion side (upper substrate 46 side), and the potential of the second electrode 44 becomes higher than that of the third electrode 45B. Consequently, a potential difference occurs between the first electrode 45A and the third electrode 45B, and for example, in a case where a load is connected to the end of the electrode, electric power can be extracted. At this time, the first electrode 45A becomes a positive electrode, and the third electrode 45B becomes a negative electrode.

### Fifth Embodiment

The thermoelectric conversion element 140 can obtain a higher voltage by, for example, alternately disposing a plurality of p-type thermoelectric conversion layers 41, 41 . . . and a plurality of n-type thermoelectric conversion layers 42, 42, . . . and connecting them to each other in series through the first and third electrodes 45 and the second electrode 44, as shown in FIG. 5.

As shown in FIG. 5, in the present invention, a plurality of thermoelectric conversion elements may be electrically connected to each other so as to constitute a so-called module (thermoelectric conversion module).

Hereinafter, each of the members constituting the thermoelectric conversion element will be specifically described.

[Substrate]

As the substrates in the thermoelectric conversion element (the first substrate 12 and the second substrate 16 in the first embodiment, the first substrate 22 and the second substrate 26 in the second embodiment, the low thermal conduction portions 32a and 30a in the third embodiment, and the upper substrate 46 and the lower substrate 43 in the fourth embodiment), substrates such as glass, transparent ceramics, and a plastic film, and the like can be used. In the thermoelectric conversion element of the present invention, it is preferable that the substrate has flexibility. Specifically, the substrate preferably has such flexibility that the substrate is found to have an MIT folding endurance of equal to or greater than 10,000 cycles by a measurement method specified by ASTM D2176. As the substrate has such flexibility, a plastic film is preferable, and specific examples thereof include a polyester film such as polyethylene terephthalate, polyethylene isophthalate, polyethylene naphthalate, polybutylene terephthalate, poly(1,4-cyclohexylenedimethyleneterephthalate), polyethylene-2,6-naphthalenedicarboxylate, or a polyester film of bisphenol A and isophthalic and terephthalic acids, a polycycloolefin film such as a ZEONOR film (trade name, manufactured by ZEON CORPORATION), an ARTON film (trade name, manufactured by JSR Corporation), or SUMILITE FS1700 (trade name, manufactured by Sumitomo Bakelite Co. Ltd.), a polyimide film such as KAPTON (trade name, manufactured by DU PONT-TORAY CO., LTD.), APICAL (trade name, manufactured by Kaneka Corporation), UPILEX (trade name, manufactured by UBE INDUSTRIES, LTD.), or POMIRAN (trade name, manufactured by Arakawa Chemical Industries, Ltd.), a polycarbonate film such as PUREACE (trade name, manufactured by TEIJIN LIMITED) or ELMEC (trade name, manufactured by Kaneka Corporation), a polyether ether ketone film such as SUMILITE FS1100 (trade name, manufactured by Sumitomo Bakelite Co. Ltd.), a polyphenyl sulfide film such as TORELINA (trade name, manufactured by TORAY INDUSTRIES, INC.), and the like. From the viewpoint of ease of availability, heat resistance (preferably equal to or higher than 100° C.), economic feasibility, and effects, commercially available polyethylene terephthalate, polyethylene naphthalate, various polyimide or polycarbonate films, and the like are preferable.

In view of handleability, durability, and the like, the thickness of the substrate is preferably 5 to 3,000 μm, more preferably 10 to 1,000 μm, even more preferably 12.5 to 500 μm, and particularly preferably 12.5 to 100 μm. In a case where the thickness of the substrate is within the above range, the thermal conductivity is not reduced, and the thermoelectric conversion layer is not easily damaged due to an external shock.

[Electrode]

As electrode materials forming the electrodes in the thermoelectric conversion element, it is possible to use a transparent electrode material such as Indium-Tin-Oxide (ITO) or ZnO, a metal electrode material such as silver, copper, gold, or aluminum, a carbon material such as CNT or graphene, an organic material such as poly(3,4-ethylenedioxythiophene) (PEDOT)/polystyrene sulfonate (PSS), a conductive paste in which conductive fine particles of silver, carbon, and the like are dispersed, a conductive paste containing metal nanowires of silver, copper, or aluminum, and the like. Among these, a metal electrode material such as aluminum, gold, silver, or copper or a conductive paste containing these metals is preferable.

[p-Type Thermoelectric Conversion Layer]

As the p-type thermoelectric conversion layer included in the thermoelectric conversion element of the fourth embodiment, a known p-type thermoelectric conversion layer can be used. As materials contained in the p-type thermoelectric conversion layer, it is possible to appropriately use known materials (for example, a composite oxide such as NaCo₂O₄ or Ca₃Co₄O₉, a silicide such as MnSi_{1.73}, Fe₁₋ₓMnₓSi₂, Si_{0.8}Ge_{0.2}, or β-FeSi₂, skutterudite such as CoSb₃, FeSb₃, or RFe₃CoSb₁₂ (R represents La, Ce, or Yb), and a Te-containing alloy such as BiTeSb, PbTeSb, Bi₂Te₃, or PbTe) and CNT.

The method for forming (manufacturing) the n-type thermoelectric conversion layer can be the same as the method for manufacturing the thermoelectric conversion layer of the present invention described above, and specific examples thereof are as described above.

[Article for Thermoelectric Power Generation]

The article for thermoelectric power generation of the present invention is an article for thermoelectric power generation using the thermoelectric conversion element of the present invention.

Specific examples of the article for thermoelectric power generation include a generator such as a hot spring heat power generator, a solar power generator, or a waste heat power generator, a power supply for a wrist watch, a power supply for driving a semiconductor, a power supply for a small sensor, and the like.

That is, the aforementioned thermoelectric conversion element of the present invention can be suitably used for the above purposes.

[Composition for Forming Thermoelectric Conversion Layer]

The definition, the specific examples, and the suitable aspect of the composition for forming a thermoelectric conversion layer of the present invention are the same as those of the thermoelectric conversion layer described above.

### EXAMPLES

Hereinafter, the present invention will be more specifically described based on examples, but the present invention is not limited thereto.

### Example 1 (Method a)

<Preparation of Composition for Forming Thermoelectric Conversion Layer>

First, single-layer CNT was pretreated. Specifically, by using a mechanical homogenizer (manufactured by SMT Corporation, HIGH-FLEX HOMOGENiZER HF93), 500 mg of single-layer CNT (CNT described in Table 1: C1) and 250 mL of acetone were mixed together for 5 minutes at 18,000 rpm, thereby obtaining a dispersion liquid. The dispersion liquid was filtered under reduced pressure by using a Buchner funnel and a suction bottle, thereby obtaining a cloth-like CNT film (buckypaper). The cloth-like CNT was cut in a size equal to or smaller than 1 cm and used for the preparation of a CNT dispersion liquid (composition for forming a thermoelectric conversion layer) as the next step.

Then, 1,200 mg of sodium deoxycholate (manufactured by TOKYO CHEMICAL INDUSTRY CO., LTD.) as a dispersant, 100 mg of carboxymethyl cellulose sodium salt (CMC-Na: manufactured by Sigma-Aldrich Co. LLC., high-viscosity resin) as a hydrogen bonding resin, and 400 mg of EMULGEN 350 (manufactured by Kao Corporation) as a dopant for a change to an n-type were dissolved in 16 mL of water as a dispersion solvent, and 400 mg of the single-layer CNT (CNT described in Table 1: C1) pretreated as described above was added thereto. The composition was mixed for 7 minutes by using a mechanical homogenizer (manufactured by SMT Corporation, HIGH-FLEX HOMOGENiZER HF93), thereby obtaining a premix. By using a thin film revolution-type high-speed mixer “FILMIX 40-40 model” (manufactured by PRIMIX Corporation), a dispersion treatment was performed on the obtained premix in a constant-temperature tank with a temperature of 10° C. for 2 minutes at a circumferential speed of 10 m/sec and then for 5 minutes at a circumferential speed of 40 m/sec by a high-speed revolution thin film dispersion method. By using a rotation⋅revolution mixer (manufactured by THINKY CORPORATION, AWATORI RENTARO), the obtained dispersion composition was mixed for 30 seconds at 2,000 rpm and defoamed for 30 seconds at 2,200 rpm, thereby preparing a CNT dispersion liquid (composition for forming a thermoelectric conversion layer).

CNT (C1 to C3) used in the present example is shown in Table 1.

In the table, “Diameter” and “Diameter distribution” mean the values calculated by the method described above, and “GD ratio” means the intensity ratio between a G-band and a D-band in a Raman spectrum.

Furthermore, “e-Dips method” means an enhanced Direct Injection Pyrolytic Synthesis.

C2 and C3 used in Examples 32 and 33 were also pretreated in the same manner as in Example 1.

TABLE 1

| | C1 | | C2 | | C3 | |
|---|---|---|---|---|---|---|
| Manufacturer | OCSiAl | | OCSiAl | | Meijo Nano | |
| | | | | | Carbon Co., Ltd. | |
| Manufacturing | Arc method | | Arc method | | e-Dips method | |
| method | | | | | | |
| Diameter | 1.34 | nm | 1.85 | nm | 1.43 | nm |
| Diameter | 1.10 to 1.68 | nm | 1.30 to 4.01 | nm | 1.18 to 2.51 | nm |
| distribution | | | | | | |

| | | | |
|---|---|---|---|
| Diameter | 0.58 | 2.71 | 1.33 |
| distribution | | | |
| width | | | |
| GD ratio | 40.1 | 32.8 | 49.6 |

<Manufacturing of Thermoelectric Conversion Layer>

A frame made of TEFLON (registered trademark, the same is true for the following description) was attached to a glass substrate having a thickness of 1.1 mm and a size of 40 mm×50 mm, and the area in the frame was coated with the obtained composition for forming a thermoelectric conversion layer. The substrate was dried for 30 minutes at 50° C. and then for 30 minutes at 120° C., then immersed in ethanol for 1 hour so as to remove the dispersant, and then dried for 30 minutes at 50° C. and then for 150 minutes at 120° C., thereby obtaining a film (thermoelectric conversion layer). The thickness of the obtained thermoelectric conversion layer was 7.1 μm.

### Examples 2 to 29 and 32 to 36 and Comparative Examples 1 to 4 and 6 (Method a)

CNT dispersion liquid (compositions for forming a thermoelectric conversion layer) of Examples 2 to 29 and 32 to 36 and Comparative Examples 1 to 4 and 6 were prepared based on the same preparation method as that in Example 1, except that the type of CNT, the dispersant, the solvent, and the hydrogen bonding resin, the amount of CNT, the dispersant, the solvent, and the hydrogen bonding resin added, the type of the dopant for a change to an n-type, the amount of the dopant for a change to an n-type added, and the thickness of the thermoelectric conversion layer were changed as described in Table 2. Then, a film (thermoelectric conversion layer) was formed by the same method as that in Example 1. For Examples 34 to 36, the thickness of the frame made of TEFLON was changed such that the thickness of the thermoelectric conversion layer was adjusted.

“Low-viscosity CMC-Na” described in the column of “Hydrogen bonding resin” in Table 2 is a carboxymethyl cellulose sodium salt (low-viscosity resin manufactured by Sigma-Aldrich Co. LLC.), “PVA” is polyvinyl alcohol, “PVP” is polyvinyl pyrrolidone, and “PAA-Na” is sodium polyacrylate.

“PEO20 stearyl ether” described in the column of “Hydrogen bonding resin” in Table 2 is a higher alcohol ethylene oxide adduct manufactured by Wako Pure Chemical Industries, Ltd., and “PEO (Mw=1,000)” is a polyoxyethylene having a weight-average molecular weight of 1,000.

### Example 30 (Method b)

<Preparation of CNT Dispersion Liquid>

First, single-layer CNT was pretreated. Specifically, by using a mechanical homogenizer (manufactured by SMT Corporation, HIGH-FLEX HOMOGENiZER HF93), 500 mg of single-layer CNT (CNT described in Table 1: C1) and 250 mL of acetone were mixed together for 5 minutes at 18,000 rpm, thereby obtaining a dispersion liquid. The dispersion liquid was filtered under reduced pressure by using a Buchner funnel and a suction bottle, thereby obtaining a cloth-like CNT film (buckypaper). The cloth-like CNT was cut in a size equal to or smaller than 1 cm and used for the preparation of a CNT dispersion liquid (composition for forming a thermoelectric conversion layer) as the next step.

1,200 mg of sodium deoxycholate (manufactured by TOKYO CHEMICAL INDUSTRY CO., LTD.) as a dispersant and 100 mg of carboxymethyl cellulose sodium salt (manufactured by Sigma-Aldrich Co. LLC., low-viscosity resin) as a hydrogen bonding resin were dissolved in 16 mL of water as a dispersion medium, and 400 mg of the single-layer CNT (CNT described in Table 1: C1) pretreated as described above was added thereto. The composition was mixed for 7 minutes by using a mechanical homogenizer (manufactured by SMT Corporation, HIGH-FLEX HOMOGENiZER HF93), thereby obtaining a premix. By using a thin film revolution-type high-speed mixer “FILMIX 40-40 model” (manufactured by PRIMIX Corporation), a dispersion treatment was performed on the obtained premix in a constant-temperature tank with a temperature of 10° C. for 2 minutes at a circumferential speed of 10 m/sec and then for 5 minutes at a circumferential speed of 40 m/sec by a high-speed revolution thin film dispersion method. By using a rotation⋅revolution mixer (manufactured by THINKY CORPORATION, AWATORI RENTARO), the obtained dispersion composition was mixed for 30 seconds at 2,000 rpm and defoamed for 30 seconds at 2,200 rpm, thereby preparing a CNT dispersion liquid.

<Preparation of Thermoelectric Conversion Layer Precursor>

Subsequently, a frame made of TEFLON was attached to a glass substrate having a thickness of 1.1 mm and a size of 40 mm×50 mm, and the area in the frame was coated with the CNT dispersion liquid. The substrate was dried for 30 minutes at 50° C. and then for 30 minutes at 120° C., then immersed in ethanol for 1 hour so as to remove the dispersant, and dried for 30 minutes at 50° C. and then for 150 minutes at 120° C., thereby obtaining a film (thermoelectric conversion layer precursor). The thickness of the thermoelectric conversion layer was 7 μm.

<Change to n-Type Through Doping>

50 mg of cobaltocene was dissolved in 10 ml of toluene. The obtained film (thermoelectric conversion layer precursor) was cut in 1 cm×1 cm and immersed in the solution. After 3 hours, the film was taken out and dried for 30 minutes at 50° C. and then for 150 minutes at 120° C., thereby obtaining a film (thermoelectric conversion layer).

### Example 31 and Comparative Example 5 (Method b)

CNT dispersion liquids (compositions for forming a thermoelectric conversion layer) of Example 31 and Comparative Example 5 were prepared based on the same preparation method as that in Example 30, except that the type of the hydrogen bonding resin, the amount of the hydrogen bonding resin added, the type of the dopant for a change to an n-type, and the immersion solvent were changed as described in Table 2.

Then, the formation of a thermoelectric conversion layer precursor and the change to an n-type through doping were performed by the same method as that in Example 30, a film (thermoelectric conversion layer) was obtained.

[Evaluation]

The obtained thermoelectric conversion layer was evaluated as below.

<Seebeck Coefficient and Electric Conductivity>

The thermoelectric conversion layer formed on a glass substrate as described above was cut in 1 cm, and by using a thermoelectric characteristic measuring device MODEL RZ2001i (manufactured by OZAWA SCIENCE CO., LTD.), a Seebeck coefficient (thermoelectromotive force per absolute temperature of 1 K) and an electric conductivity at 80° C. and 120° C. were measured. By interpolation, a Seebeck coefficient and an electric conductivity at 100° C. were calculated. The results are shown in Table 2. The evaluation standards are as below.

(Seebeck Coefficient)
AA: less than −50 uV/K
A: equal to or greater than −50 uV/K and less than −40 uV/K
B: equal to or greater than −40 uV/K and less than −30 uV/K
C: equal to or greater than −30 uV/K and less than −20 uV/K
D: equal to or greater than −20 uV/K and less than −0 uV/K
E: equal to or greater than 0 uV/K (changed into a p-type)

(Electric Conductivity)
AA: equal to or higher than 800 S/cm
A: equal to or higher than 600 S/cm and less than 800 S/cm
B: equal to or higher than 400 S/cm and less than 600 S/cm
C: equal to or higher than 200 S/cm and less than 400 S/cm
D: less than 200 S/cm

<Power Factor (PF)>

The power factor was calculated from the following equation.

(Power factor)=(electric conductivity)×(Seebeck coefficient)²

The results are shown in Table 2. The evaluation standards are as below. The higher the power factor, the more preferable. For practical use, the thermoelectric conversion layers graded AA to B according to the following evaluation standards are preferable.
AA: equal to or higher than 200 uW/mK²
A: equal to or higher than 150 uW/mK² and less than 200 uW/mK²
B: equal to or higher than 120 uW/mK² and less than 150 uW/mK²
C: equal to or higher than 90 uW/mK² and less than 120 uW/mK²
D: equal to or higher than 50 uW/mK² and less than 90 uW/mK²
E: less than 50 uW/mK²

The thermal conductivity was calculated from the following equation.

(Thermal conductivity [W/Mk])=(specific heat [J/kg·K])×(density [kg/m³])×(thermal diffusivity [m²/s])

“Specific heat” in the above equation was measured by a Differential scanning calorimetry (DSC) method, and “density” was measured by mass/volume. “Thermal diffusivity” was measured using a thermal diffusivity measuring device ai-Phase Mobile 1u (manufactured by ai-Phase Co., Ltd).

The results are shown in Table 2. The evaluation standards are as below. The lower the thermal conductivity, the more preferable. For practical use, the thermoelectric conversion layers graded AA to B according to the following evaluation standards are preferable.
AA: less than 1 W/mk
A: equal to or higher than 1 W/mK and less than 2 W/mK
B: equal to or higher than 2 W/mK and less than 3 W/mK
C: equal to or higher than 3 W/mK and less than 4 W/mK
D: equal to or higher than 4 W/mK and less than 5 W/mK
E: equal to or higher than 5 W/mK

<Performance Stability of Thermoelectric Conversion Layer Exposed to High Temperature for Long Period of Time>

The thermoelectric conversion layer formed on a glass substrate as described above was stored for 30 days in the atmospheric environment at 80° C. (high-temperature environment test). Then, a Seebeck coefficient thereof was measured. The Seebeck coefficient was measured by the method described above. Thereafter, from the Seebeck coefficients measured before and after the high-temperature environment test, a rate of change (shown below) of a Seebeck coefficient caused by the high-temperature environment test was calculated, and the performance stability of the thermoelectric conversion layer exposed to a high temperature for a long period of time was evaluated. The results are shown in Table 2. The evaluation standards are as below. The lower the rate of change, the more preferable. For practical use, the thermoelectric conversion layers graded AA to B according to the following evaluation standards are preferable.

Rate of change of Seebeck coefficient caused by high-temperature environment test/%=(X−Y)/X×100

X=Seebeck coefficient before high-temperature environment test

Y=Seebeck coefficient after high-temperature environment test
AA: less than 3%
A: equal to or higher than 3% and less than 5%
B: equal to or higher than 5% and less than 10%
C: equal to or higher than 10% and less than 20%
D: equal to or higher than 20% and less than 30%
E: equal to or higher than 30%

TABLE 2

| | | | | | | | | Dopant for change to n type | | |
|---|---|---|---|---|---|---|---|---|---|---|
| | | | | | | | | | | Amount |
| | | | | | Hydrogen bonding resin | | | | | of |
| | | | | | | | Amount | | | dopant |
| | | | | | | | of hy- | | Method | for a |
| | | | | | | | drogen | | a: | change |
| | | | | | | | bonding | | added | to |
| | | | | | | | resin | | amount | n-type |
| | | | | | | | with | | Method | with |
| | | | | | | | respect | | b: dis- | respect |
| | | Type | | | | Added | to CNT | | solved | to CNT |
| | | of | | | | amount | (% by | | amount | (% by |
| | Method | CNT | Dispersant | Solvent | Type | (g) | mass) | Type | (g) | mass) |
| Example 1 | a | C1 | Sodium deoxycholate | Water | High-viscosity CMC-Na | 0.1 | 25 | EMULGEN 350 | 0.4 | 100 |
| Example 2 | a | C1 | Sodium deoxycholate | Water | Low-viscosity CMC-Na | 0.01 | 2.5 | EMULGEN 350 | 0.4 | 100 |
| Example 3 | a | C1 | Sodium deoxycholate | Water | Low-viscosity CMC-Na | 0.03 | 7.5 | EMULGEN 350 | 0.4 | 100 |
| Example 4 | a | C1 | Sodium deoxycholate | Water | Low-viscosity CMC-Na | 0.05 | 12.5 | EMULGEN 350 | 0.4 | 100 |
| Example 5 | a | C1 | Sodium deoxycholate | Water | Low-viscosity CMC-Na | 0.1 | 25 | EMULGEN 350 | 0.4 | 100 |
| Example 6 | a | C1 | Sodium deoxycholate | Water | Low-viscosity CMC-Na | 0.2 | 50 | EMULGEN 350 | 0.4 | 100 |
| Example 7 | a | C1 | Sodium deoxycholate | Water | Low-viscosity CMC-Na | 0.3 | 75 | EMULGEN 350 | 0.4 | 100 |
| Example 8 | a | C1 | Sodium deoxycholate | Water | Low-viscosity CMC-Na | 0.2 | 50 | EMULGEN 350 | 0.03 | 7.5 |
| Example 9 | a | C1 | Sodium deoxycholate | Water | Low-viscosity CMC-Na | 0.2 | 50 | EMULGEN 350 | 0.05 | 12.5 |
| Example 10 | a | C1 | Sodium deoxycholate | Water | Low-viscosity CMC-Na | 0.2 | 50 | EMULGEN 350 | 0.1 | 25 |
| Example 11 | a | C1 | Sodium deoxycholate | Water | Low-viscosity CMC-Na | 0.2 | 50 | EMULGEN 350 | 0.6 | 150 |
| Example 12 | a | C1 | Sodium deoxycholate | Water | Low-viscosity CMC-Na | 0.2 | 50 | EMULGEN 350 | 0.8 | 200 |
| Example 13 | a | C1 | Sodium cholate | Water | Low-viscosity CMC-Na | 0.2 | 50 | EMULGEN 350 | 0.4 | 100 |
| Example 14 | a | C1 | Sodium deoxycholate | Water | Low-viscosity CMC-Na | 0.2 | 50 | PEO20 stearyl efher | 0.4 | 100 |
| Example 15 | a | C1 | Sodium deoxycholate | Water | Low-viscosity CMC-Na | 0.2 | 50 | PEO(Mw 1000) | 0.4 | 100 |
| Example 16 | a | C1 | Sodium deoxycholate | Water | Alginic acid | 0.1 | 25 | EMULGEN 350 | 0.4 | 100 |
| Example 17 | a | C1 | Sodium deoxycholate | Water | Na alginate | 0.1 | 25 | EMULGEN 350 | 0.4 | 100 |
| Example 18 | a | C1 | Sodium deoxycholate | Water | Xanthan gum | 0.1 | 25 | EMULGEN 350 | 0.4 | 100 |
| Example 19 | a | C1 | Sodium deoxycholate | Water | Xylan | 0.1 | 25 | EMULGEN 350 | 0.4 | 100 |
| Example 20 | a | C1 | Sodium deoxycholate | Water | Low-viscosity CMC-Na | 0.2 | 50 | Cobaltocene | 0.2 | 50 |
| Example 21 | a | C1 | Sodium deoxycholate | Water | Low-viscosity CMC-Na | 0.2 | 50 | Stearylamine | 0.2 | 50 |
| Example 22 | a | C1 | Sodium deoxycholate | Water | Low-viscosity CMC-Na | 0.2 | 50 | Triphenylphosphine | 0.2 | 50 |
| Example 23 | a | C1 | Sodium deoxycholate | Water | Low-viscosity CMC-Na | 0.2 | 50 | 1,3-Bis(diphenyl- | 0.2 | 50 |
| | | | | | | | | phosphine)propane | | |
| Example 24 | a | C1 | Sodium deoxycholate | Water | Na alginate | 0.1 | 25 | Stearylamine | 0.2 | 50 |
| Example 25 | a | C1 | Sodium deoxycholate | Water | PVA | 0.1 | 25 | EMULGEN 350 | 0.4 | 100 |
| Example 26 | a | C1 | Sodium deoxycholate | Water | PVP | 0.1 | 25 | EMULGEN 350 | 0.4 | 100 |
| Example 27 | a | C1 | Sodium deoxycholate | Water | PAA-Na | 0.1 | 25 | EMULGEN 350 | 0.4 | 100 |
| Example 28 | a | C1 | Sodium deoxycholate | Water | PVP | 0.1 | 25 | Stearylamine | 0.2 | 50 |
| Example 29 | a | C1 | Sodium deoxycholate | Water | PAA-Na | 0.1 | 25 | Triphenylphosphine | 0.2 | 50 |
| Example 30 | b | C1 | Sodium deoxycholate | Water | Low-viscosity CMC-Na | 0.1 | 25 | Cobaltocene | 0.05 | — |
| Example 31 | b | C1 | Sodium deoxycholate | Water | Low-viscosity CMC-Na | 0.1 | 25 | Stearylamine | 0.05 | — |
| Example 32 | a | C2 | Sodium deoxycholate | Water | Low-viscosity CMC-Na | 0.2 | 50 | EMULGEN 350 | 0.4 | 100 |
| Example 33 | a | C3 | Sodium deoxycholate | Water | Low-viscosity CMC-Na | 0.2 | 50 | EMULGEN 350 | 0.4 | 100 |
| Example 34 | a | C1 | Sodium deoxycholate | Water | Low-viscosity CMC-Na | 0.2 | 50 | EMULGEN 350 | 0.4 | 100 |
| Example 35 | a | C1 | Sodium deoxycholate | Water | Low-viscosity CMC-Na | 0.2 | 50 | EMULGEN 350 | 0.4 | 100 |
| Example 36 | a | C1 | Sodium deoxycholate | Water | Low-viscosity CMC-Na | 0.2 | 50 | EMULGEN 350 | 0.4 | 100 |
| Comparative | a | C1 | Sodium deoxycholate | Water | N/A | — | — | N/A | — | — |
| Example 1 | | | | | | | | | | |
| Comparative | a | C1 | Sodium deoxycholate | Water | High-viscosity CMC-Na | 0.1 | 25 | N/A | — | — |
| Example 2 | | | | | | | | | | |
| Comparative | a | C1 | Sodium deoxycholate | Water | N/A | — | — | Tribenzylamine | 0.4 | 100 |
| Example 3 | | | | | | | | | | |
| Comparative | a | C1 | Sodium deoxycholate | Water | N/A | — | — | Triphenylphosphine | 0.4 | 100 |
| Example 4 | | | | | | | | | | |
| Comparative | b | C1 | Sodium deoxycholate | Water | N/A | — | — | Triphenylphosphine | 0.05 | — |
| Example 5 | | | | | | | | | | |
| Comparative | a | C1 | Polystyrene | Methyl | N/A | — | — | Triphenylphosphine | 0.4 | 100 |
| Example 6 | | | | carbitol | | | | | | |

| | | | | Evaluation result | | | | | |
|---|---|---|---|---|---|---|---|---|---|
| | | | | | | | | | Performance |
| | Hydrogen | | | | | | | | stability |
| | bonding | | Thickness of | | | | | | of thermoelectric |
| | resin/dopant | | thermoelectric | | | | | | conversion layer |
| | for a change | | conversion | Thermoelectric conversion performance | | | | | exposed to high |
| | to an n-type | Immersion | layer | | Seebeck | Electric | | Thermal | temperature for long |
| | (mass ratio) | solvent | (μm) | type | coefficient | conductivity | PF | conductivity | period of time |
| Example 1 | 1/4 | — | 7.1 | N | AA | AA | AA | AA | AA |
| Example 2 | 1/40 | — | 5.9 | N | AA | AA | AA | A | A |
| Example 3 | 3/40 | — | 6.5 | N | AA | AA | AA | A | A |
| Example 4 | 1/8 | — | 6.2 | N | AA | AA | AA | AA | A |
| Example 5 | 1/4 | — | 6.8 | N | AA | AA | AA | AA | AA |
| Example 6 | 1/2 | — | 7.6 | N | AA | AA | AA | AA | AA |
| Example 7 | 3/4 | — | 8.4 | N | AA | A | A | AA | AA |
| Example 8 | 6.7 | — | 8.1 | N | A | A | A | AA | AA |
| Example 9 | 4 | — | 7.7 | N | A | AA | A | AA | AA |
| Example 10 | 2 | — | 7.5 | N | AA | AA | AA | AA | AA |
| Example 11 | 1/3 | — | 7.7 | N | A | AA | A | AA | AA |
| Example 12 | 1/4 | — | 7.8 | N | A | A | A | AA | AA |
| Example 13 | 1/2 | — | 8.2 | N | AA | AA | AA | AA | AA |
| Example 14 | 1/2 | — | 6.8 | N | AA | AA | AA | AA | AA |
| Example 15 | 1/2 | — | 6.5 | N | AA | AA | AA | AA | AA |
| Example 16 | 1/4 | — | 8.1 | N | AA | A | A | A | AA |
| Example 17 | 1/4 | — | 8 | N | AA | A | A | A | AA |
| Example 18 | 1/4 | — | 6.9 | N | AA | A | A | A | AA |
| Example 19 | 1/4 | — | 6.8 | N | A | A | A | A | AA |
| Example 20 | 1 | — | 9.1 | N | A | A | A | AA | A |
| Example 21 | 1 | — | 7.2 | N | A | A | A | AA | A |
| Example 22 | 1 | — | 7.2 | N | A | A | A | AA | A |
| Example 23 | 1 | — | 8.3 | N | A | A | A | AA | A |
| Example 24 | 1/2 | — | 7.9 | N | A | B | B | A | A |
| Example 25 | 1/4 | — | 6.2 | N | A | B | B | A | A |
| Example 26 | 1/4 | — | 7.5 | N | A | B | B | A | A |
| Example 27 | 1/4 | — | 6 | N | A | B | B | A | A |
| Example 28 | 1/2 | — | 5.9 | N | B | B | B | A | B |
| Example 29 | 1/2 | — | 7.6 | N | B | B | B | A | B |
| Example 30 | — | Toluene | 7 | N | B | C | B | AA | A |
| Example 31 | — | MEK | 7 | N | B | C | B | AA | A |
| Example 32 | 1/2 | — | 7.5 | N | A | AA | A | AA | AA |
| Example 33 | 1/2 | — | 9.1 | N | AA | AA | AA | A | AA |
| Example 34 | 1/2 | — | 3.2 | N | AA | A | AA | AA | A |
| Example 35 | 1/2 | — | 1.1 | N | B | A | B | A | B |
| Example 36 | 1/2 | — | 21.2 | N | AA | AA | AA | AA | AA |
| Comparative | — | — | 6.5 | P | E | — | — | — | — |
| Example 1 | | | | | | | | | |
| Comparative | — | — | 7.5 | P | E | — | — | — | — |
| Example 2 | | | | | | | | | |
| Comparative | — | — | 7.2 | N | D | D | E | E | E |
| Example 3 | | | | | | | | | |
| Comparative | — | — | 7.3 | N | C | C | C | E | E |
| Example 4 | | | | | | | | | |
| Comparative | — | Tolulene | 6.9 | N | C | D | D | E | E |
| Example 5 | | | | | | | | | |
| Comparative | — | — | 11.1 | N | C | D | D | C | E |
| Example 6 | | | | | | | | | |

In Table 2, “Immersion solvent” means the solvent used for the change to an n-type through doping in the method b, and “MEK” represents methyl ethyl ketone. Furthermore, “type” shows that whether the obtained thermoelectric conversion layer is a p-type or an n-type.

As is evident from Table 2, it was confirmed that Examples 1 to 36 containing a hydrogen bonding resin have a high power factor and a low thermal conductivity and exhibit excellent performance stability in a case where the thermoelectric conversion layer is exposed to a high temperature for a long period of time. Particularly, it was confirmed that in a case where a thermoelectric conversion layer is prepared using a cellulose derivative as a hydrogen bonding resin and CNT plus an oxyalkylene-based compound as a CNT-containing n-type thermoelectric conversion material, the thermoelectric conversion performance of the obtained thermoelectric conversion layer tends to be further improved, and the thermoelectric conversion layer tends to exhibit higher performance stability even being exposed to a high temperature for a long period of time.

As is evident from the comparison between Examples 1 to 7, it was confirmed that in a case where the amount of a hydrogen bonding resin with respect to CNT is 12% to 70% by mass, a higher power factor and a lower thermal conductivity can be simultaneously achieved, and in a case where the amount of a hydrogen bonding resin with respect to CNT is 13% to 50% by mass, the thermoelectric conversion layer exhibits higher performance stability even being exposed to a high temperature for a long period of time.

As is evident from the comparison between Examples 8 to 12, in a case where the amount of a dopant for a change to an n-type with respect to CNT is 12% to 150% by mass, the thermoelectric conversion performance is further improved, and in a case where the amount of a dopant for a change to an n-type with respect to CNT is 20% to 100% by mass, a higher power factor is exhibited.

From the comparison between Example 5, Examples 16 to 19, and Examples 25 to 27, it was confirmed that in a case where a polysaccharide is used as a hydrogen bonding resin (Example 5 and Examples 16 to 19), the power factor further increases, the thermal conductivity further decreases, and the thermoelectric conversion layer exhibits higher performance stability even exposed to a high temperature for a long period of time. Particularly, in a case where a polysaccharide having a carboxyl group or a salt is used (Example 5 and Examples 16 to 18), more preferably, in a case where a cellulose derivative is used (Example 5) as a polysaccharide, the aforementioned effects are further improved.

From the comparison between Example 6, Examples 14 and 15, and Examples 20 to 24, it was confirmed that in a case where a polyoxyethylene-based compound is used as a dopant for a change to an n-type (Example 6 and Examples 14 and 15), the power factor tends to further increase, and the thermal conductivity tends to further decrease.

From the comparison between Examples 5, 32, and 33, it was confirmed that in Example 5, in which the carbon nanotubes have a diameter equal to or smaller than 1.5 nm and the diameter distribution is equal to or smaller than 2.0 nm, a higher power factor and a lower thermal conductivity can be simultaneously achieved.

From the comparison between Examples 34 to 36, in a case where the thickness of the thermoelectric conversion layer is set to be 2 to 300 μm (preferably 3 to 200 μm and more preferably 5 to 100 μm), the thermoelectric conversion performance of the obtained thermoelectric conversion layer is further improved, and the thermoelectric conversion layer exhibits higher performance stability even being exposed to a high temperature for a long period of time.

In contrast, it was confirmed that in all of Comparative Examples 1 to 6, the thermoelectric conversion performance (particularly, the power factor and the thermal conductivity) is poor, and the thermoelectric conversion layer exhibits poor performance stability in a case where the thermoelectric conversion layer is exposed to a high temperature for a long period of time.

Particularly, it was confirmed that in Comparative Examples 1 and 2, an aspect is adopted in which the thermoelectric conversion layer contains none of the hydrogen bonding resin and the dopant for a change to an n-type, and accordingly, the obtained thermoelectric conversion layer has a low power Seebeck coefficient and exhibits the properties of a p-type.

[Thermoelectric Conversion Element]

An n-type thermoelectric conversion element and a p-n junction thermoelectric conversion element were prepared in the following manner.

According to the same procedure as that in the examples and the comparative examples described above, a thermoelectric conversion layer was formed. By using the thermoelectric conversion layer as an n-type thermoelectric conversion layer, an n-type thermoelectric conversion element and a p-n junction thermoelectric conversion element corresponding to each of the examples and the comparative examples described above were prepared and evaluated in the same manner as described above.

As a result, it was confirmed that the same results as those shown in Table 2 are obtained, and even in a case where a thermoelectric conversion element was prepared using the thermoelectric conversion layer, a high power factor and a low thermal conductivity are obtained, and the thermoelectric conversion element exhibits excellent performance stability even being exposed to a high temperature for a long period of time.

<n-Type Thermoelectric Conversion Element>

As a substrate, a glass substrate having a thickness of 1.1 mm and a size of 40 mm×50 mm was used. The substrate was subjected to ultrasonic cleaning in acetone and then subject to a UV-ozone treatment for 10 minutes. Thereafter, a first electrode and a second electrode made of gold having a size of 30 mm×5 mm and a thickness of 10 nm were formed on each of both end portion sides of the substrate.

A frame made of TEFLON was attached onto a substrate on which the electrodes were formed, and the CNT dispersion liquid prepared as described above was poured into the space in the frame. The substrate was dried for 30 minutes at 50° C. and then for 30 minutes at 120° C., immersed in ethanol for 1 hour so as to remove the dispersant, and dried for 30 minutes at 50° C. and then for 150 minutes at 120° C. After drying, the frame was detached, an n-type thermoelectric conversion layer having a thickness of about 7 μm was formed (for the method b, the change to an n-type through doping was also performed to form the n-type thermoelectric conversion layer), thereby preparing a thermoelectric conversion element 120 (n-type thermoelectric conversion element) constituted as shown in FIG. 2.

<p-n Junction Thermoelectric Conversion Element>

(Composition for Forming p-Type Thermoelectric Conversion Layer)

First, single-layer CNT was pretreated. Specifically, by using a mechanical homogenizer (manufactured by SMT Corporation, HIGH-FLEX HOMOGENiZER HF93), 500 mg of single-layer CNT (Tuball manufactured by OCSiAl) and 250 mL of acetone were mixed together for 5 minutes at 18,000 rpm, thereby obtaining a dispersion liquid. The dispersion liquid was filtered under reduced pressure by using a Buchner funnel and a suction bottle, thereby obtaining a cloth-like CNT film (buckypaper). The cloth-like CNT was cut in a size equal to or smaller than 1 cm and used for the preparation of a CNT dispersion liquid (composition for forming a thermoelectric conversion layer) as the next step.

1,200 mg of sodium deoxycholate (manufactured by TOKYO CHEMICAL INDUSTRY CO., LTD.) as a dispersant was dissolved in 16 mL of water as a solvent, and 400 mg of the single-layer CNT (Tuball manufactured by OCSiAl) pretreated as described above was added thereto. The composition was mixed for 7 minutes by using a mechanical homogenizer (manufactured by SMT Corporation, HIGH-FLEX HOMOGENiZER HF93), thereby obtaining a premix. By using a thin film revolution-type high-speed mixer “FILMIX 40-40 model” (manufactured by PRIMIX Corporation), a dispersion treatment was performed on the obtained premix in a constant-temperature tank with a temperature of 10° C. for 2 minutes at a circumferential speed of 10 m/sec and then for 5 minutes at a circumferential speed of 40 m/sec by a high-speed revolution thin film dispersion method. By using a rotation⋅revolution mixer (manufactured by THINKY CORPORATION, AWATORI RENTARO), the obtained dispersion composition was mixed for 30 seconds at 2,000 rpm and defoamed for 30 seconds at 2,200 rpm, thereby preparing a CNT dispersion liquid.

(Preparation of p-Type Thermoelectric Conversion Element)

By using the composition for forming a p-type thermoelectric conversion layer as a dispersion liquid, a p-type thermoelectric conversion element was prepared through the same preparation step as that used for preparing the thermoelectric conversion element 120.

(Preparation of p-n junction thermoelectric conversion element)

The electrodes in the thermoelectric conversion element 120 were connected to the electrodes in the p-type thermoelectric conversion element through conductive wire, thereby preparing a p-n junction thermoelectric conversion element (thermoelectric conversion element in which the p-type thermoelectric conversion layer and the n-type thermoelectric conversion layer are electrically connected to each other).

### EXPLANATION OF REFERENCES

110, 120, 130, 140: thermoelectric conversion element
11, 17: metal plate
12, 22: first substrate
13, 23: first electrode
14, 24: n-type thermoelectric conversion layer
15, 25: second electrode
16, 26: second substrate
30: second substrate
32: first substrate
32a, 30a: low thermal conduction portion
32b, 30b: high thermal conduction portion
34: n-type thermoelectric conversion layer
36: first electrode
38: second electrode
41: p-type thermoelectric conversion layer
42: n-type thermoelectric conversion layer
43: lower substrate
44: second electrode
45: first and third electrodes
45A: first electrode
45B: third electrode
46: upper substrate
47: hole
48: electron

What is claimed is:

1. A thermoelectric conversion layer comprising:
a carbon nanotube-containing n-type thermoelectric conversion material; and
a hydrogen bonding resin.

2. The thermoelectric conversion layer according to claim 1,
wherein the carbon nanotube-containing n-type thermoelectric conversion material contains carbon nanotubes and at least one kind of dopant for a change to an n-type.

3. The thermoelectric conversion layer according to claim 2,
wherein in the carbon nanotube-containing n-type thermoelectric conversion material, a content of the dopant for a change to an n-type is 7% to 200% by mass with respect to a content of the carbon nanotubes.

4. The thermoelectric conversion layer according to claim 2,
wherein a content of the hydrogen bonding resin is 2% to 80% by mass with respect to the content of the carbon nanotubes.

5. The thermoelectric conversion layer according to claim 2,
wherein the dopant for a change to an n-type is at least one kind of compound selected from the group consisting of a polyoxyalkylene-based compound, an amine-based compound, and a phosphine-based compound.

6. The thermoelectric conversion layer according to claim 1,
wherein the hydrogen bonding resin is a polysaccharide.

7. The thermoelectric conversion layer according to claim 6,
wherein the hydrogen bonding resin has a carboxyl group or a salt thereof.

8. The thermoelectric conversion layer according to claim 7,
wherein the hydrogen bonding resin is a cellulose derivative.

9. The thermoelectric conversion layer according to claim 2,
wherein the dopant for a change to an n-type is a polyoxyalkylene-based compound.

10. A thermoelectric conversion element comprising:
the thermoelectric conversion layer according to claim 1 as an n-type thermoelectric conversion layer.

11. The thermoelectric conversion element according to claim 10, further comprising:
a p-type thermoelectric conversion layer electrically connected to the n-type thermoelectric conversion layer,
wherein the p-type thermoelectric conversion layer contains carbon nanotubes.

12. A composition for forming a thermoelectric conversion layer, comprising:
a carbon nanotube-containing n-type thermoelectric conversion material; and
a hydrogen bonding resin.

13. The composition for forming a thermoelectric conversion layer according to claim 12,
wherein the carbon nanotube-containing n-type thermoelectric conversion material contains carbon nanotubes and at least one kind of dopant for a change to an n-type.

14. The composition for forming a thermoelectric conversion layer according to claim 13,
wherein in the carbon nanotube-containing n-type thermoelectric conversion material, a content of the dopant for a change to an n-type is 7% to 200% by mass with respect to a content of the carbon nanotubes.

15. The composition for forming a thermoelectric conversion layer according to claim 13,
wherein a content of the hydrogen bonding resin is 2% to 80% by mass with respect to the content of the carbon nanotubes.

16. The composition for forming a thermoelectric conversion layer according to claim 13,
wherein the dopant for a change to an n-type is at least one kind of compound selected from the group consisting of a polyoxyalkylene-based compound, an amine-based compound, and a phosphine-based compound.

17. The composition for forming a thermoelectric conversion layer according to claim 12,
wherein the hydrogen bonding resin is a polysaccharide.

18. The composition for forming a thermoelectric conversion layer according to claim 17,
wherein the hydrogen bonding resin has a carboxyl group or a salt thereof.

19. The composition for forming a thermoelectric conversion layer according to claim 18,
wherein the hydrogen bonding resin is a cellulose derivative.

20. The composition for forming a thermoelectric conversion layer according to claim 13,
wherein the dopant for a change to an n-type is a polyoxyalkylene-based compound.
